(19) United States
(12) Patent Application Publication
(10) Pub. No.: US 2026/0068432 A1
(43) Pub. Date: Mar. 5, 2026

(54) DISPLAY DEVICE, AND ELECTRONIC DEVICE INCLUDING THE SAME

(71) Applicant: Samsung Display Co., LTD., Yongin-si (KR)

(72) Inventors: KEUNWOO KIM, Yongin-si (KR); SOYOUNG KOO, Yongin-si (KR); SANGSUB KIM, Yongin-si (KR); BUMMO SUNG, Yongin-si (KR); SEUNGJUN LEE, Yongin-si (KR)

(21) Appl. No.: 19/063,678

(22) Filed: Feb. 26, 2025

(30) Foreign Application Priority Data
Sep. 2, 2024 (KR) 10-2024-0118359

(51) Int. Cl. H10K 59/121; H10K 59/131

(52) U.S. Cl. CPC H10K 59/1213; H10K 59/131

(57) ABSTRACT

A display device includes: a first active layer disposed on a substrate and including a first driving channel portion and a second driving channel portion which is spaced apart from the first driving channel portion; a first gate pattern disposed on the first active layer, overlapping each of the first driving channel portion and the second driving channel portion in a plan view, and exposing a portion of the first active layer which is disposed between the first driving channel portion and the second driving channel portion; a second gate pattern disposed on the first gate pattern, overlapping the first gate pattern in a plan view, and exposing a portion of the first gate pattern; and a light-emitting element disposed on the second gate pattern.

This application claims priority to Korean Patent Application No. 10-2024-0118359, filed on Sep. 2, 2024, and all the benefits accruing therefrom under 35 U.S.C. § 119, the content of which in its entirety is herein incorporated by reference.

### BACKGROUND

### 1. Field

Embodiments relate to a display device. More particularly, the embodiments relate to the display device providing a visual information.

### 2. Description of the Related Art

A display device may include a plurality of pixels. Each of the pixels may include a plurality of transistors including a driving transistor, a capacitor, a light-emitting element, and the like. The driving transistor included in each pixel may generate a driving current, and the light-emitting element included in each pixel may emit light with a brightness corresponding to a magnitude of the driving current. A voltage-current characteristic of the driving transistor may have hysteresis that varies depending on an operating state of the driving transistor in a previous display frame. Since the hysteresis characteristic is related to a problem of an afterimage remaining on a screen of the display device, research is currently being conducted to improve the hysteresis characteristic of the driving transistor.

### SUMMARY

Embodiments provide a display device with an improved display quality.

A display device according to an embodiment includes a first active layer disposed on a substrate and including a first driving channel portion and a second driving channel portion which is spaced apart from the first driving channel portion, a first gate pattern disposed on the first active layer, overlapping each of the first driving channel portion and the second driving channel portion in a plan view, and exposing a portion of the first active layer which is disposed between the first driving channel portion and the second driving channel portion, a second gate pattern disposed on the first gate pattern, overlapping the first gate pattern in a plan view, and exposing a portion of the first gate pattern, and a light-emitting element disposed on the second gate pattern.

In an embodiment, the display device may further include a bottom metal layer disposed between the substrate and the first active layer in a cross-sectional view, and overlapping each of the first driving channel portion and the second driving channel portion in the plan view.

In an embodiment, the bottom metal layer may expose at least a portion of a rear surface of the portion of the first active layer which is disposed between the first driving channel portion and the second driving channel portion.

In an embodiment, an area of the bottom metal layer may be greater than an area of the first gate pattern.

In an embodiment, the bottom metal layer may overlap an entirety of the first gate pattern in the plan view.

In an embodiment, an area of the bottom metal layer may be substantially equal to an area of the first gate pattern.

In an embodiment, a shape of the first gate pattern may be substantially the same as a shape of the bottom metal layer in the plan view.

In an embodiment, the display device may further include a first electrode and a second electrode, which are disposed on the second gate pattern and electrically connected to the first active layer, and the first active layer, the first gate pattern, the first electrode, and the second electrode may define a driving transistor together.

In an embodiment, the driving transistor may include a first sub-transistor including the first driving channel portion and a second sub-transistor including the second driving channel portion.

In an embodiment, the display device may further include a second active layer disposed on the second gate pattern, a third gate pattern disposed on the second active layer, and a third electrode and a fourth electrode disposed on the third gate pattern and disposed in the same layer as the first electrode and the second electrode, and the second active layer, the third gate pattern, the third electrode, and the fourth electrode may define a compensation transistor or an initialization transistor.

In an embodiment, the first active layer may include a silicon semiconductor, and the second active layer may include an oxide semiconductor.

In an embodiment, a length of the first driving channel portion may be greater than a length of the second driving channel portion.

In an embodiment, a length of the first driving channel portion may be substantially equal to a length of the second driving channel portion.

In an embodiment, the first driving channel portion and the second driving channel portion may be symmetrical with respect to an imaginary line passing through a center of the first active layer which is disposed between the first driving channel portion and the second driving channel portion in the plan view.

In an embodiment, a portion of the first gate pattern exposed by the second gate pattern may overlap the first driving channel portion in the plan view.

In an embodiment, a portion of the first gate pattern exposed by the second gate pattern may overlap the second driving channel portion in the plan view.

A display device according to an embodiment includes a data write transistor configured to transmit a data voltage to a first node in response to a write signal, a driving transistor configured to generate a driving current corresponding to the data voltage and including a first sub-transistor which includes a first terminal connected to the first node, a second terminal opposite to the first terminal, and a gate terminal connected to a second node and a second sub-transistor which includes a first terminal connected to the second terminal of the first sub-transistor, a second terminal connected to a third node, and a gate terminal connected to the second node, a storage capacitor configured to store the data voltage and including a first terminal connected to the second node and a second terminal configured to receive a driving voltage, and a light-emitting element which emits light with a brightness corresponding to the driving current.

In an embodiment, the first sub-transistor and the second sub-transistor may be connected in series between the first node and the third node.

In an embodiment, the display device may further include a compensation transistor including a first terminal connected to the third node, a second terminal connected to the fourth node, and a gate terminal configured to receive a compensation signal and an initialization transistor including a first terminal connected to the fourth node, a second terminal configured to receive an initialization voltage, and a gate terminal configured to receive an initialization signal.

In an embodiment, each of the compensation transistor and the initialization transistor may be NMOS.

In an embodiment, wherein each of the compensation transistor and the initialization transistor may be PMOS.

In an embodiment, the display device may further include a first active layer including a first driving channel portion which defines a channel of the first sub-transistor and a second driving channel portion which defines a channel of the second sub-transistor and a first gate pattern disposed on the first active layer and defining the gate terminal f the first sub-transistor and the gate terminal of the second sub-transistor.

In an embodiment, the first gate pattern may expose a portion of the first active layer disposed between the first driving channel portion and the second driving channel portion.

In an embodiment, the display device may further include a second gate pattern disposed on the first gate pattern and defining the second terminal of the storage capacitor, and the second gate pattern may expose a portion of the first gate pattern.

In an embodiment, the display device may further include a bottom metal layer disposed between a substrate and the first active layer in a cross-sectional view, and overlapping each of the first driving channel portion and the second driving channel portion in a plan view, and the bottom metal layer exposes at least a rear surface of the portion of the first active layer disposed between the first driving channel portion and the second driving channel portion.

In an embodiment, each of the first sub-transistor and the second sub-transistor may further include a bottom gate terminal, and the bottom metal layer may define the bottom gate terminal of the first sub-transistor and the bottom gate terminal of the second sub-transistor.

In a display device according to embodiments of the present disclosure, the display device may include a first active layer including a first driving channel portion and a second driving channel portion, a first gate pattern disposed on the first active layer, a second gate pattern disposed on the first gate pattern, and a bottom metal layer disposed under the first active layer. Accordingly, since a driving transistor included in the display device may have a dual transistor structure including two channels, a channel length is relatively reduced compared to a case that the driving transistor has one driving channel, and thus a hysteresis characteristic of the display device may be improved.

In addition, the first gate pattern may expose a portion of an upper surface of the first active layer between the first driving channel portion and the second driving channel portion, the second gate pattern may expose an upper surface of the first gate pattern, and the bottom metal layer may expose a rear surface of the first active layer. Accordingly, a movement path of hydrogen ions (H⁺) emitted from the first active layer and diffusing to an upper portion of the second gate pattern may be reduced, thereby facilitating an emission of the hydrogen ions from the first active layer. In addition, light introduced from a lower portion of the bottom metal layer may be introduced toward a periphery of the first driving channel portion and the second driving channel portion. Accordingly, a decrease in each of a driving range of the driving transistor and a swing width of a data voltage may be reduced. Accordingly, when a black screen and a white screen are alternately displayed in a screen of the display device, a phenomenon in which an afterimage or stain is momentarily visible on the screens may be effectively prevented.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a circuit diagram illustrating an example of a pixel included in the display device of FIG. 1.

FIG. 3 is a circuit diagram illustrating another example of a pixel included in the display device of FIG. 1.

FIG. 4 is a circuit diagram illustrating still another example of a pixel included in the display device of FIG. 1.

FIGS. 5, 6, 7, 8, 9, 10, 11, 12, 13, 14, 15, and 16 are layout views illustrating a pixel included in the display device of FIG. 1.

FIG. 17 is a cross-sectional view illustrating a cross-section taken along line X-Y of FIG. 1.

FIG. 18 is a layout view illustrating a first transistor according to an embodiment.

FIG. 19 is a cross-sectional view illustrating a cross-section taken along line I-I′ of FIG. 18.

FIG. 20 is a view for explaining light inflow through a bottom metal layer of FIG. 19 and hydrogen emission from a first active layer.

FIG. 21 is a layout view illustrating a first transistor according to another embodiment.

FIG. 22 is a cross-sectional view illustrating a cross-section taken along line II-II′ of FIG. 21.

FIG. 23 is a layout view illustrating a first transistor according to still another embodiment.

FIG. 24 is a cross-sectional view illustrating a cross-section taken along line III-III′ of FIG. 21.

FIG. 25 is a layout view illustrating a first transistor according to yet another embodiment.

FIG. 26 is a layout view illustrating a first transistor according to still another embodiment.

FIG. 27 is a layout view illustrating a first transistor according to yet another embodiment.

FIG. 28 is a block diagram illustrating an electronic device according to an embodiment.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third”, “first-first”, “first-second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

“About” or “substantially equal” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially equal” can mean within one or more standard deviations, or within +10%, 5% or 2% of the stated value.

Hereinafter, display devices in accordance with embodiments will be described in more detail with reference to the accompanying drawings. The same reference numerals are used for the same components in the drawings, and redundant descriptions of the same components will be omitted.

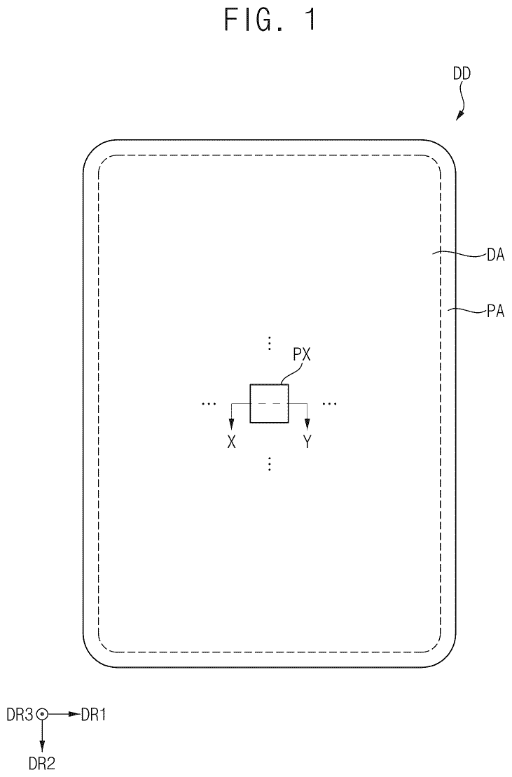

FIG. 1 is a plan view illustrating a display device according to an embodiment of the present disclosure.

In this specification, a “plan view” may be defined as a view in a thickness direction (third direction DR3) of the display device DD. The third direction DR3 may be perpendicular to a plane defined by a first direction DR1 and a second direction DR2 perpendicular to each other.

Referring to FIG. 1, a display device DD according to an embodiment of the present disclosure may include a display area DA and peripheral area PA. The display area DA may be defined as an area which generates a light, or displays an image by adjusting a transmittance of a light provided from the outside light source.

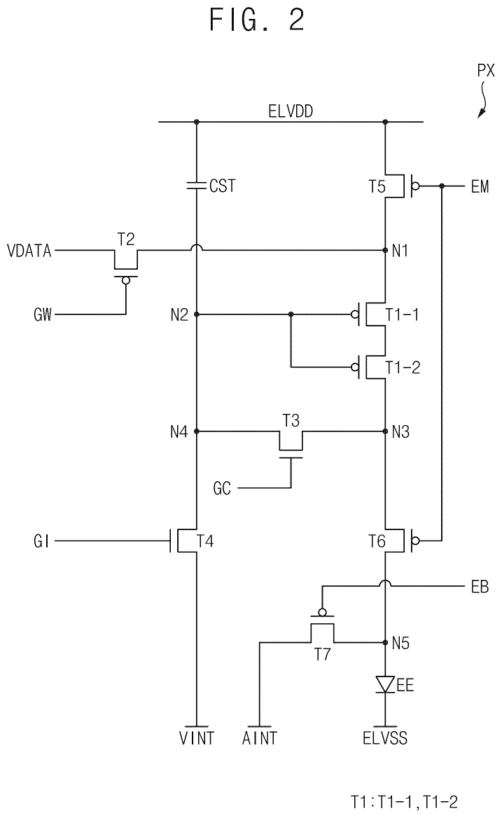

A plurality of pixels PX may be disposed in the display area DA. For example, each of the plurality of pixels PX may include a driving element (e.g., first, second, third, fourth, fifth, sixth, and seventh transistors T1, T2, T3, T4, T5, T6, and T7 of FIG. 2) and a light-emitting element (e.g., the light-emitting element EE of FIG. 2). The pixels PX may be disposed along the first direction DR1 and the second direction DR2 intersecting the first direction DR1. For example, the pixels PX may be disposed in a matrix form along the first direction DR1 and the second direction DR2.

The peripheral area PA may be defined as an area that does not display an image. In addition, the peripheral area PA may surround at least a portion of the display area DA. For example, the peripheral area PA may surround the entirety of the display area DA.

A driver electrically connected to a pixel PX may be disposed in a peripheral area PA. For example, the driver may include a data driver, a gate driver, and the like The data driver may transmit a data signal to the pixel PX, and the gate driver may transmit a gate signal to the pixel PX. Specifically, the pixel PX may be connected to a data line electrically connected to the data driver and extending along the second direction DR2 and a gate line electrically connected to the gate driver and extending along the first direction DR1. Accordingly, the pixel PX may emit light corresponding to each of the data signal and the gate signal. However, a direction in which each of the data line and the gate line according to embodiments of the present disclosure extends may not be limited thereto.

FIG. 2 is a circuit diagram illustrating an example of a pixel included in the display device of FIG. 1.

Referring to FIG. 2, the pixel PX may include a first transistor T1, a second transistor T2, a third transistor T3, a fourth transistor T4, a fifth transistor T5, a sixth transistor T6, a seventh transistor T7, a storage capacitor CST, and a light-emitting element EE. The first transistor T1 may include a first sub-transistor T1-1 and a second sub-transistor T1-2.

The first sub-transistor T1-1 may include a first terminal connected to a first node N1, a second terminal opposite to the first terminal, and a gate terminal connected to a second node N2. The second sub-transistor T1-2 may include a first terminal connected to the second terminal of the first sub-transistor T1-1, a second terminal connected to a third node N3, and a gate terminal connected to the second node N2. In an embodiment, the first sub-transistor T1-1 and the second sub-transistor T1-2 may be connected in series between the first node N1 and the third node N3.

The first terminal of the first sub-transistor T1-1 may be connected to a data voltage line, and the second terminal of the second sub-transistor T1-2 may be connected to the light-emitting element EE. Accordingly, the first transistor T1 may receive a data voltage DATA from the data voltage line and generate a driving current corresponding to the data voltage DATA. The driving current may be provided to the light-emitting element EE. In this specification, the first transistor T1 may be referred to as a “driving transistor”.

The second transistor T2 may include a first terminal connected to the data voltage line, a second terminal connected to the first node N1, and a gate terminal provided with a write signal GW. Accordingly, the second transistor T2 may be turned on or off by the write signal GW. During a period in which the second transistor T2 is turned on, the second transistor T2 may provide the data voltage DATA to the first transistor T1. In other words, the second transistor T2 may transmit the data voltage DATA to the first node N1 in response to the write signal GW. For example, in this specification, the second transistor T2 may be referred to as a “data write transistor”.

The third transistor T3 may include a first terminal connected to the third node N3, a second terminal connected to the fourth node N4, and a gate terminal provided with a compensation signal GC. Accordingly, the third transistor T3 may be turned on or off by the compensation signal GC. During a period in which the third transistor T3 is turned on, the third transistor T3 may compensate for a threshold voltage of the first transistor T1 by diode-connecting the first transistor T1. In this specification, the third transistor T3 may be referred to as a “compensation transistor”.

The fourth transistor T4 may include a first terminal connected to the fourth node N4, a second terminal connected to the first initialization voltage line, and a gate terminal provided with the first initialization signal GI. Accordingly, the fourth transistor T4 may be turned on or off by the first initialization signal GI. During a period in which the fourth transistor T4 is turned on, the fourth transistor T4 may provide the first initialization voltage VINT provided by the first initialization voltage line to the gate terminal of the first transistor T1. In this specification, the fourth transistor T4 may be referred to as an “initialization transistor”.

The fifth transistor T5 may include a first terminal connected to a first power voltage line, a second terminal connected to the first node N1, and a gate terminal connected to the light-emitting control line. The light light-emitting control line may provide a light-emitting control signal EM to the gate terminal of the fifth transistor T5. Accordingly, the fifth transistor

T5 may be turned on or off by the light-emitting control signal EM. During a period in which the fifth transistor T5 is turned on, the fifth transistor T5 may provide a first power voltage ELVDD provided by the first power voltage line to the first transistor T1.

In an embodiment, the first power voltage ELVDD provided by the first power voltage line and a second power voltage ELVSS provided by the second power voltage line connected to the light-emitting element EE may each be a constant voltage. In an embodiment, the first power voltage ELVDD and the second power voltage ELVSS may have different voltage levels. In this specification, the first power voltage ELVDD may be referred to as a “driving voltage”.

The sixth transistor T6 may include a first terminal connected to the third node N3, a second terminal connected to the fifth node N5, and a gate terminal connected to the light-emitting control line. Accordingly, the sixth transistor T6 may be turned on or off by the light-emitting control signal EM. During a period in which the sixth transistor T6 is turned on, the sixth transistor T6 may provide the driving current to the light-emitting element EE.

The seventh transistor T7 may include a first terminal connected to the second initialization voltage line, a second terminal connected to the fifth node N5, and a gate terminal provided with a bypass signal EB. Accordingly, the seventh transistor T7 may be turned on or off by the bypass signal EB. During the portion where the seventh transistor T7 is turned on, the seventh transistor T7 may provide the second initialization voltage AINT provided by the second initialization voltage line to the light-emitting element EE.

The storage capacitor CST may include a first terminal connected to the second node N2 and a second terminal connected to the first power voltage line. The storage capacitor CST may maintain voltage levels of each of the gate terminal of the first sub-transistor T1-1 and the gate terminal of the second sub-transistor T1-2 during an inactivation period of the write signal GW.

The light-emitting element EE may include a first terminal (e.g., an anode terminal) and a second terminal (e.g., a cathode terminal), and the first terminal of the light-emitting element EE is connected to the sixth transistor T6 and the seventh transistor T7, and the second terminal may receive the second power voltage ELVSS. The light emitting element EE may generate light having a brightness corresponding to the driving current.

In an embodiment, each of the first transistor T1, the second transistor T2, the fifth transistor T5, the sixth transistor T6, and the seventh transistor T7 may be a PMOS transistor. In an embodiment, the third transistor T3 may be an NMOS. In an embodiment, the fourth transistor T4 may be an NMOS. Accordingly, active patterns of each of the first transistor T1, the second transistor T2, the fifth transistor T5, the sixth transistor T6, and the seventh transistor T7 may include a silicon semiconductor doped with a cation, and the active patterns of each of the third transistor T3 and the fourth transistor T4 may include an oxide semiconductor.

In addition, the write signal GW, the light-emitting control signal EM and the bypass signal EB for turning on each of the second transistor T2, the fifth transistor T5, the sixth transistor T6 and the seventh transistor T7 may have a negative voltage level, and the compensation signal GC and the first initialization signal GI for turning on each of the third transistor T3 and the fourth transistor T4 may have a positive voltage level. However, types of each of the first, second, third, fourth, fifth, sixth, and seventh transistors T1, T2, T3, T4, T5, T6, and T7 according to the embodiments of the present disclosure and the voltage levels of the signals applied to each gate terminal may not be limited thereto.

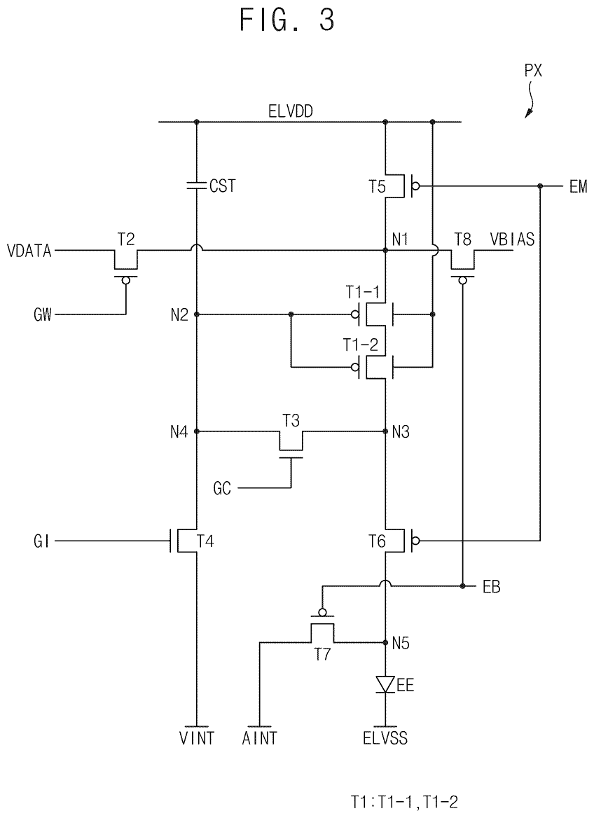

FIG. 3 is a circuit diagram illustrating another example of a pixel included in the display device of FIG. 1.

The pixel PX of FIG. 3 may have substantially the same structure as the structure described with reference to FIG. 2, except for the connection relationship between the pixel PX and the first transistor T1, and a eighth transistor T8. Hereinafter, any content overlapping with a structure of the pixel PX described with reference to FIG. 2 will be omitted or simplified.

Referring to FIG. 3, the pixel PX may include an eighth transistor T8. The eighth transistor T8 may include a first terminal connected to a first node N1, a second terminal connected to a bias voltage line to which a bias voltage VBIAS is applied, and a gate terminal provided with a bypass signal EB. Accordingly, the eighth transistor T8 may be turned on or off by the bypass signal EB. During a period in which the eighth transistor T8 is turned on, the eighth transistor T8 may provide the bias voltage VBIAS to the first transistor T1.

Each of the first sub-transistor T1-1 and the second sub-transistor T1-2 may be a dual-gate transistor. For example, each of the first sub-transistor T1-1 and the second sub-transistor T1-2 may include a bottom gate terminal. The bottom gate terminal of the first sub-transistor T1-1 and the bottom gate terminal of the second sub-transistor T1-2 may each be connected to the first power voltage line.

In an embodiment, each of the first transistor T1, the second transistor T2, the fifth transistor T5, the sixth transistor T6, the seventh transistor T7, and the eighth transistor T8 may be PMOS transistors. In an embodiment, each of the third transistor T3 and the fourth transistor T4 may be an NMOS transistor. However, types of the first, second, third, fourth, fifth, sixth, seventh, and eighth transistors T1, T2, T3, T4, T5, T6, T7, and T8 according to embodiments of the present disclosure may not be limited thereto.

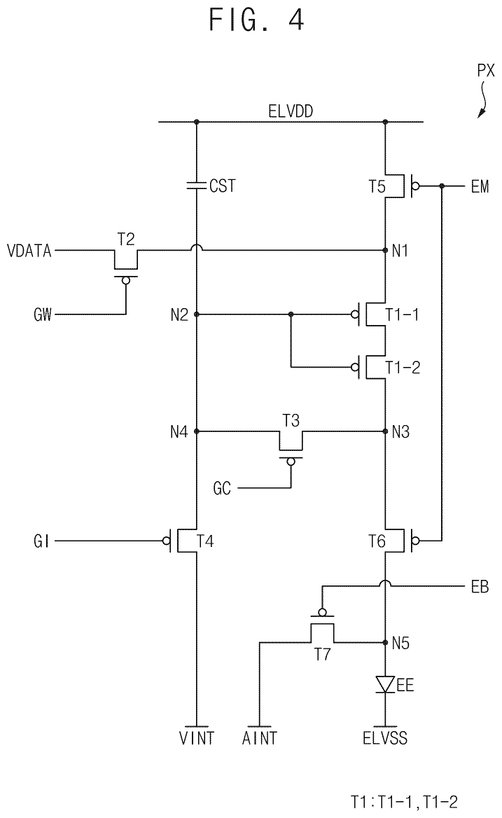

FIG. 4 is a circuit diagram illustrating still another example of a pixel included in the display device of FIG. 1.

The pixel PX of FIG. 4 may have substantially the same structure as the pixel PX described with reference to FIG. 2, except for types of the third transistor T3 and the fourth transistor T4. Hereinafter, any content overlapping with a structure of the pixel PX described with reference to FIG. 2 will be omitted or simplified.

Referring to FIG. 4, in an embodiment, each of the first, second, third, fourth, fifth, sixth, and seventh transistors T1, T2, T3, T4, T5, T6, and T7 may be a PMOS transistor. An active pattern of each of the first, second, third, fourth, fifth, sixth, and seventh transistors T1, T2, T3, T4, T5, T6, and T7 may include a silicon semiconductor doped with a cation. In addition, the compensation signal GC and the first initialization signal GI for turning on the third transistor T3 and the fourth transistor T4, respectively, may have a negative voltage level. However, a type of each of the first, second, third, fourth, fifth, sixth, and seventh transistors T1, T2, T3, T4, T5, T6, and T7 according to embodiments of the present disclosure and a voltage level of a signal applied to each gate terminal may not be limited thereto.

However, although each of the third transistor T3 and the fourth transistor T4 included in one pixel PX described with reference to FIGS. 2, 3, and 4 may be illustrated as one, structures of the third transistor T3 and the fourth transistor T4 according to embodiments of the present disclosure may not be limited thereto. For example, each of the third transistor T3 and the fourth transistor T4 may be a transistor of a dual gate structure. In an embodiment, the gate terminals of each of the third transistor T3 and the fourth transistor T4 may include a bottom gate terminal and a top gate terminal, and the bottom gate terminal and the top gate terminal may be electrically connected.

In addition, types (e.g., PMOS and NMOS) of each of the first, second, third, fourth, fifth, sixth, and seventh transistors T1, T2, T3, T4, T5, T6, and T7 described with reference to FIGS. 2, 3, and 4 and types of each of the first, second, third, fourth, fifth, sixth, seventh, and eighth transistors T1, T2, T3, T4, T5, T6, T7, and T8 described with reference to FIG. 3 may be exemplary, and types of each of the transistors included in one of the pixel PX according to the embodiments of the present disclosure may not be limited thereto. In addition, number of transistors included in one of the pixel PX described with reference to FIGS. 2, 3, and 4 may not be limited thereto, and one of the pixel PX may include 6 or less transistors or 9 or more transistors.

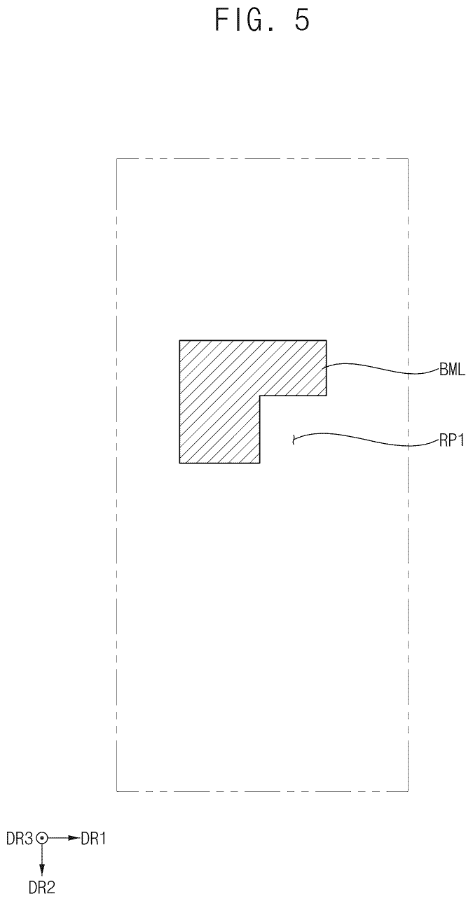

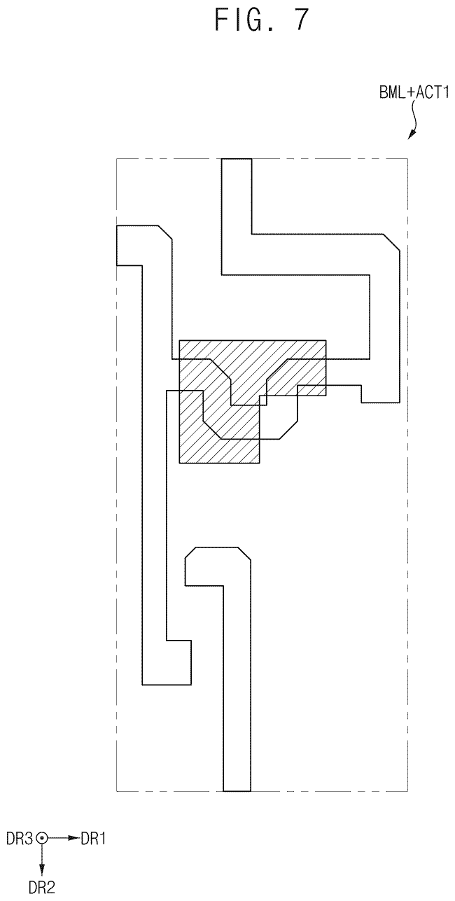

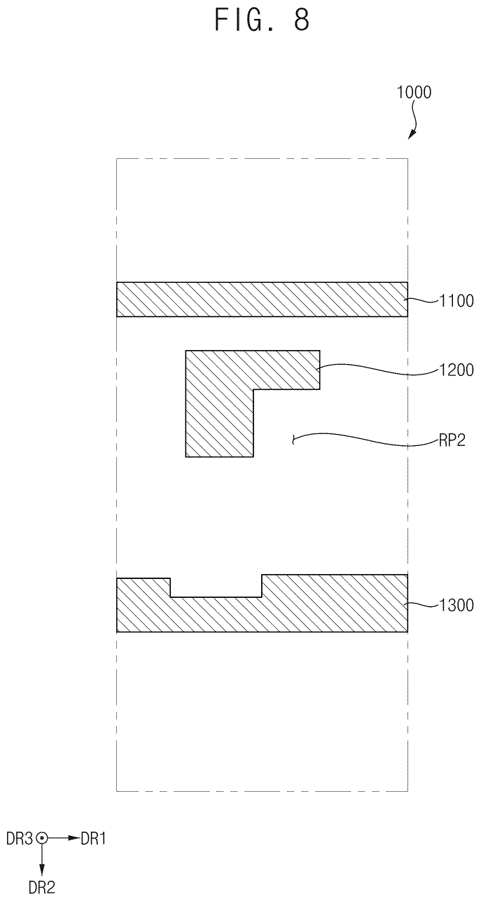

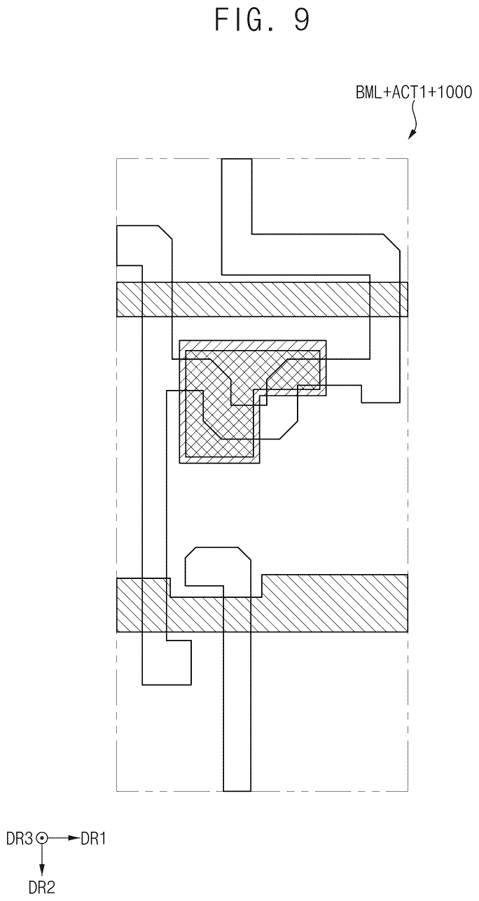

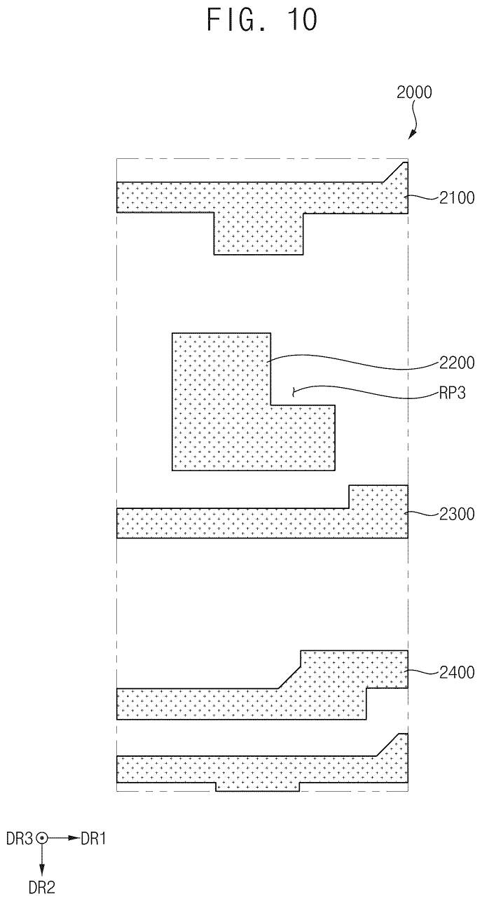

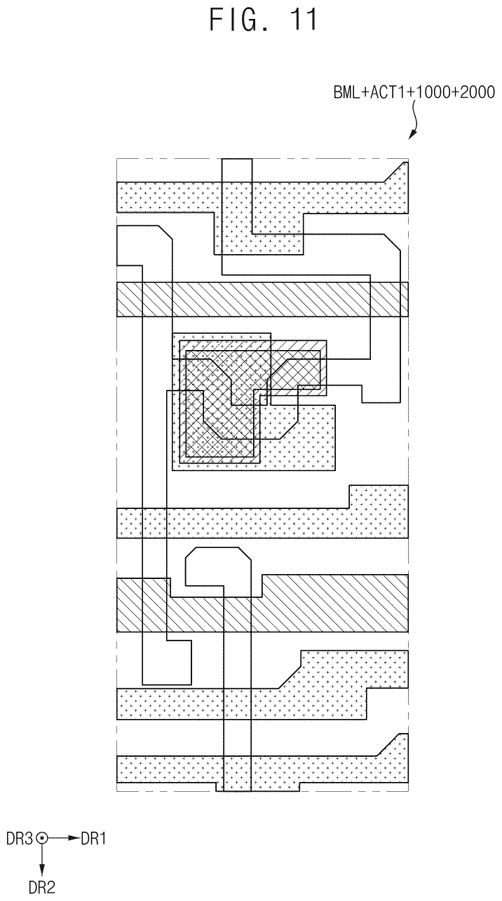

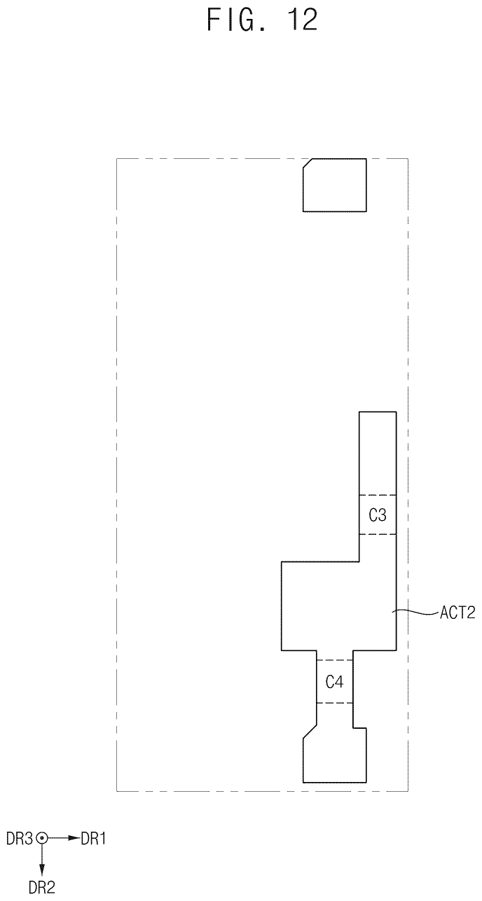

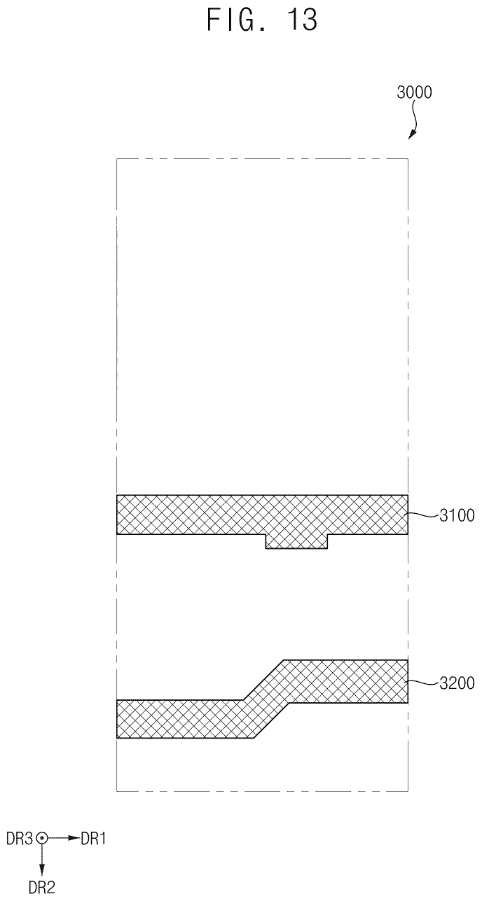

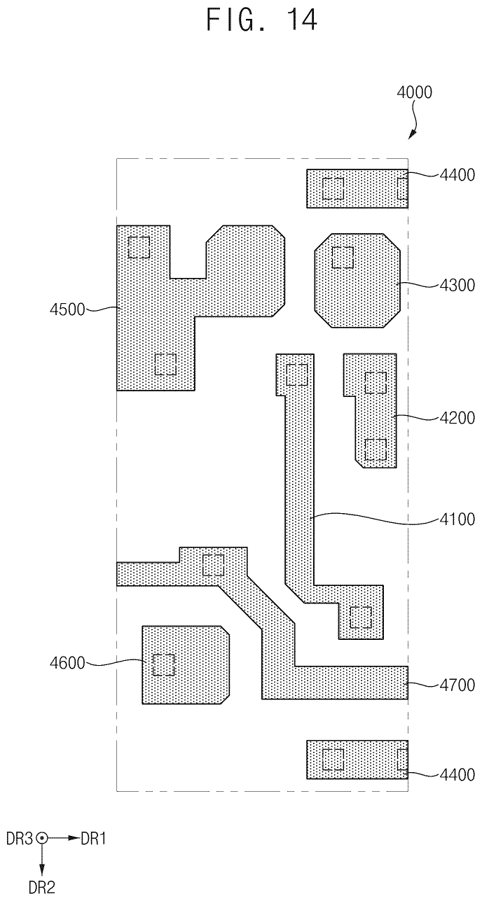

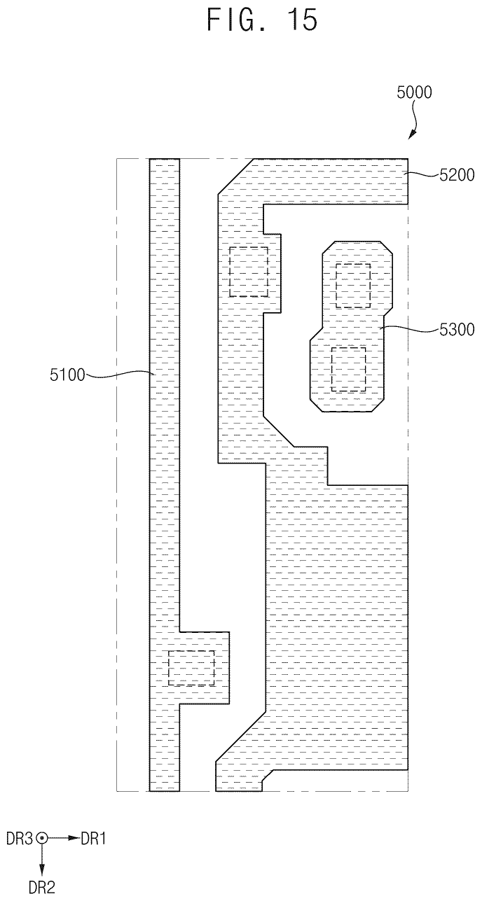

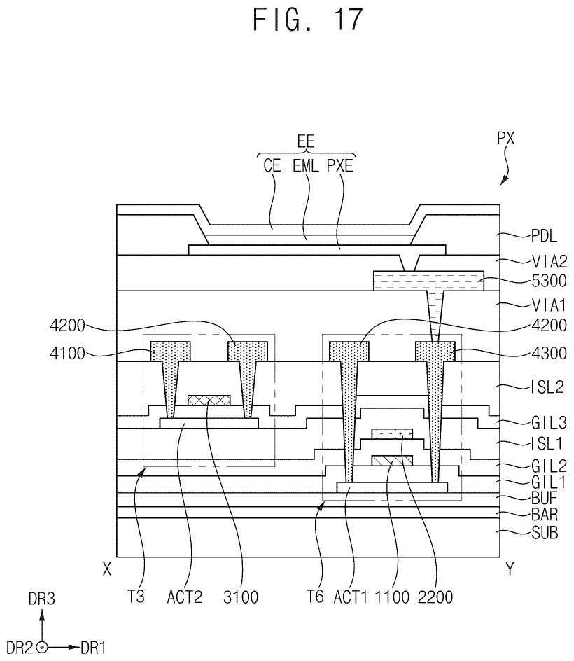

FIGS. 5, 6, 7, 8, 9, 10, 11, 12, 13, 14, 15, and 16 are layout views illustrating a pixel included in the display device of FIG. 1. FIG. 17 is a cross-sectional view illustrating a cross-section taken along line X-Y of FIG. 1. For example, FIGS. 5, 6, 7, 8, 9, 10, 11, 12, 13, 14, 15, 16, and 17 are views illustrating one of the pixel PX having the circuit diagram of FIG. 2. Referring to FIGS. 1, 2, 3, 4, 5, 6, 7, 8, 9, 10, 11, 12, 13, 14, 15, 16, and 17, the pixel

PX may include a substrate SUB, a bottom metal layer BML, a barrier layer BAR, a buffer layer BUF, a first active layer ACT1, a first gate insulating layer GIL1, a first conductive layer 1000, a second gate insulating layer GIL2, a second conductive layer 2000, a first interlayer-insulating layer ISL1, a second active pattern ACT2, a third gate insulating layer GIL3, a third conductive layer 3000, a second interlayer-insulating layer ISL2, a fourth conductive layer 4000, a first via-insulating layer VIA1, a fifth conductive layer 5000, a second via-insulating layer VIA2, a pixel electrode PXE, a pixel defining layer PDL, a light-emitting layer EML, and a common electrode CE.

The substrate SUB may serve as a base of the pixel PX. The substrate SUB may be an insulating substrate including glass, quartz, plastic, and the like. In an embodiment, the substrate SUB may include an organic insulating material such as polyimide (PI). The bottom metal layer BML may be disposed on the substrate SUB. The bottom metal layer BML may include a conductive material. For example, the conductive material may include molybdenum (Mo), copper (Cu), aluminum (Al), titanium (Ti), and the like. These may be used alone or in combination with each other. In an embodiment, the bottom metal layer BML may define a first recess RP1. For example, the bottom metal layer BML may have a concave shape in a plan view. Specifically, the bottom metal layer BML may have a curved shape defining the first recess RP1 in a plan view. However, a shape of the bottom metal layer BML in a plan view according to the embodiments of the present disclosure may not be limited thereto.

The barrier layer BAR may be disposed on the substrate SUB. The barrier layer BAR may block impurities such as oxygen, moisture, and the like. from diffusing to the upper portion of the substrate SUB through the substrate SUB. In addition, the barrier layer BAR may provide a flat upper surface on an upper portion of the substrate SUB. In an embodiment, the barrier layer BAR may include an inorganic insulating material. For example, the inorganic insulating material may include silicon nitride, silicon oxide, silicon oxynitride, and the like. These may be used alone or in combination with each other.

The buffer layer BUF may be disposed on the barrier layer BAR. The buffer layer BUF may block impurities such as oxygen, moisture, and the like. from diffusing to the upper portion of the substrate SUB through the substrate SUB. In addition, the buffer layer BUF may provide a flat upper surface on the upper portion of the substrate SUB. The buffer layer BUF may include an inorganic insulating material.

The first active layer ACT1 may be disposed on the buffer layer BUF. The first active layer ACT1 may include a first-first channel portion C1-1, a first-second channel portion C1-2, a second channel portion C2, a fifth channel portion C5, a sixth channel portion C6, and a seventh channel portion C7. The first-first channel portion C1-1, the first-second channel portion C1-2, the second channel portion C2, the fifth channel portion C5, the sixth channel portion C6, and the seventh channel portion C7 may be spaced apart from each other in a plan view. In this specification, the first-first channel portion C1-1 and the first-second channel portion C1-2 may be referred to as a “first driving channel portion” and a “second driving channel portion”, respectively.

In an embodiment, the first active layer ACT1 may include a silicon semiconductor. However, a material included in the first active layer ACT1 according to embodiments of the present disclosure may not be limited thereto, and the first active layer ACT1 may include various materials such as amorphous silicon, oxide semiconductor, and organic semiconductor.

In an embodiment, a shape of the first active layer ACT1 may be arranged repeatedly or symmetrically along the first direction DR1 in a plan view. The shape of the first active layer ACT1 may be arranged repeatedly along the second direction DR2 in a plan view.

The first-first channel portion C1-1 and the first-second channel portion C1-2 may correspond to the first sub-transistor T1-1 and the second sub-transistor T1-2, respectively. In an embodiment, the shape of the first active layer ACT1 corresponding to the first sub-transistor T1-1 and the second sub-transistor T1-2 may have a curved shape (e.g., a ‘U’ shape or an omega shape) in a plan view. Specifically, the shape of a portion of the first active layer ACT1 connected from the first-first channel portion C1-1 to the first-second channel portion C1-2 may have a ‘U’ shape or an omega shape in a plan view. However, the shape of the first active layer ACT1 according to the embodiments of the present disclosure may not be limited thereto, and the shape of the first active layer ACT1 in a plan view corresponding to the first sub-transistor T1-1 and the second sub-transistor T1-2 may not be limited thereto, and may have various shapes such as a straight shape in a plan view, an ‘S’ shape, and the like.

The first active layer ACT1 may overlap the bottom metal layer BML in a plan view. For example, the first-first channel portion C1-1 of the first active layer ACT1 and the first-second channel portion C1-2 of the first active layer ACT1 may overlap the bottom metal layer BML in a plan view, respectively.

In an embodiment, the bottom metal layer BML may expose a portion of the first active layer ACT1. For example, the bottom metal layer BML may expose at least a portion of a rear surface of the portion of the first active layer ACT1 disposed between the first-first channel portion C1-1 and the first-second channel portion C1-2. Specifically, the first recess RP1 of the bottom metal layer BML may expose the rear surface of the portion of the first active layer ACT1 disposed between the first-first channel portion C1-1 and the first-second channel portion C1-2. In other words, the first recess RP1 of the bottom metal layer BML may overlap the portion of the first active layer ACT1 disposed between the first-first channel portion C1-1 and the first-second channel portion C1-2 in a plan view.

The first gate insulating layer GIL1 may be disposed on the first active layer ACT1. In an embodiment, the first gate insulating layer GIL1 may have a uniform thickness along a profile of the first active layer ACT1. In another embodiment, the first gate insulating layer GIL1 may have a substantially flat upper surface without creating a step around the first active layer ACT1. In an embodiment, the first gate insulating layer GIL1 may include an inorganic insulating material.

The first conductive layer 1000 may be disposed on the first gate insulating layer GIL1. The first conductive layer 1000 may include a light-emitting control line 1100, a first gate pattern 1200, and a first gate voltage line 1300. In an embodiment, the first conductive layer 1000 may include a conductive material. The light-emitting control line 1100 may extend along the first direction DR1. The light-emitting control line 1100 may overlap the first active layer ACT1 in a plan view. For example, the light-emitting control line 1100 may include a first portion that overlaps the fifth channel portion C5 of the first active layer ACT1 in a plan view and a second portion that overlaps the sixth channel portion C6) of the first active layer ACT1 in a plan view. Specifically, the first portion of the light-emitting control line 1100 may correspond to the gate terminal of the fifth transistor T5. In addition, the second portion of the light-emitting control line 1100 may correspond to the gate terminal of the sixth transistor T6.

The first gate pattern 1200 may be spaced apart from the light-emitting control line 1100 in the second direction DR2. The first gate pattern 1200 may overlap the first active layer ACT1 in a plan view. For example, the first gate pattern 1200 may include a first portion that overlaps the first-first channel portion C1-1 of the first active layer ACT1 in a plan view and a second portion that overlaps the first-second channel portion C1-2 of the first active layer ACT1 in a plan view. Specifically, the first portion of the first gate pattern 1200 may correspond to the gate terminal of the first sub-transistor T1-1. In addition, the second portion of the first gate pattern 1200 may correspond to the gate terminal of the second sub-transistor T1-2.

In an embodiment, the first gate pattern 1200 may define a second recess RP2. For example, the first gate pattern 1200 may have a concave shape in a plan view. Specifically, the first gate pattern 1200 may have a curved shape defining the second recess RP2, in a plan view. However, the shape of the first gate pattern 1200 in a plan view according to embodiments of the present disclosure may not be limited thereto, and the first gate pattern 1200 may have various shapes which overlaps the first-first channel portion C1-1 and the first-second channel portion C1-2, and does not overlap a portion of the first active layer ACT1 disposed between the first-first channel portion C1-1 and the first-second channel portion C1-2, in a plan view.

In an embodiment, the first gate pattern 1200 may expose a portion of the first active layer ACT1. For example, the first gate pattern 1200 may expose a portion of the first active layer ACT1 disposed between the first-first channel portion C1-1 and the first-second channel portion C1-2. Specifically, the second recess RP2 of the first gate pattern 1200 may expose an upper surface of a portion of the first active layer ACT1 disposed between the first-first channel portion C1-1 and the first-second channel portion C1-2. In other words, the second recess RP2 of the first gate pattern 1200 may overlap the portion of the first active layer ACT1 disposed between the first-first channel portion C1-1 and the first-second channel portion C1-2 in a plan view.

In an embodiment, the entirety of the bottom metal layer BML may overlap the first gate pattern 1200 in a plan view. In an embodiment, the first gate pattern 1200 may have a shape substantially the same as the shape of the bottom metal layer BML in a plan view. The overlapping relationship between the bottom metal layer BML and the first gate pattern 1200 according to embodiments of the present disclosure may not be limited thereto. For example, the first gate pattern 1200 may have a shape different from the shape of the bottom metal layer BML in a plan view.

In an embodiment, an area of the bottom metal layer BML may be greater than an area of the first gate pattern 1200. When the area of the bottom metal layer BML is greater than the area of the first gate pattern 1200, the bottom metal layer BML may completely surround the edge of the first gate pattern 1200 in a plan view. However, an area relationship of each of the bottom metal layer BML and the first gate pattern 1200 according to embodiments of the present disclosure may not be limited thereto, and the area of the bottom metal layer BML may be substantially equal to the area of the first gate pattern 1200 in another embodiment. In other words, the area of the bottom metal layer BML in a plan view may be equal to or greater than the area of the first gate pattern 1200.

In an embodiment, the first gate pattern 1200 may overlap the bottom metal layer BML in a plan view. In an embodiment, the first recess RP1 and the second recess RP2 may overlap each other in a plan view. In an embodiment, an area of the upper surface of a portion of the first active layer ACT1 exposed by the first recess RP1 may be less than an area of a rear surface of a portion of the first active layer ACT1 exposed by the second recess RP2. However, an area of the first active layer ACT1 exposed by each of the first recess RP1 and the second recess RP2 according to embodiments of the present disclosure may not be limited thereto, and the area of the upper surface of a portion of the first active layer ACT1 exposed by the first recess RP1 may be substantially equal to the area of the rear surface of a portion of the first active layer ACT1 exposed by the second recess RP2 in another embodiment. In other words, in a plan view, the area of the upper surface of a portion of the first active layer ACT1 exposed by the first recess RP1 may be less than or equal to the area of the rear surface of a portion of the first active layer ACT1 exposed by the second recess RP2.

The first gate voltage line 1300 may extend along the first direction DR1. The first gate voltage line 1300 may be spaced apart from the light-emitting control line 1100 in the second direction DR2. The first gate voltage line 1300 may overlap the first active layer ACT1 in a plan view. For example, the first gate voltage line 1300 may include a first portion that overlaps the second channel portion C2 of the first active layer ACT1 in a plan view and a second portion that overlaps the seventh channel portion C7 of the first active layer ACT1 in a plan view. Specifically, the first portion of the first gate voltage line 1300 may correspond to the gate terminal of the second transistor T2. In addition, the second portion of the first gate pattern 1200 may correspond to the gate terminal of the seventh transistor T7. In an embodiment, when the pixel PX is included in a Nth pixel row, the second portion of the first gate voltage line 1300 may correspond to the gate terminal of the seventh transistor T7) of the pixel included in a (N+1)th pixel row.

The second gate insulating layer GIL2 may be disposed on the first conductive layer 1000. In an embodiment, the second gate insulating layer GIL2 may have a uniform thickness along a profile of the first conductive layer 1000. In another embodiment, the second gate insulating layer GIL2 may have a substantially flat upper surface without generating a step around the first conductive layer 1000. In an embodiment, the second gate insulating layer GIL2 may include an inorganic insulating material.

The second gate insulating layer GIL2 may be disposed on the first conductive layer 1000. In an embodiment, the second gate insulating layer GIL2 may have a uniform thickness along the profile of the first conductive layer 1000. In another embodiment, the second gate insulating layer GIL2 may have a substantially flat upper surface without creating a step around the first conductive layer 1000. In an embodiment, the second gate insulating layer GIL2 may include an inorganic insulating material.

The second conductive layer 2000 may be disposed on the second gate insulating layer GIL2. The second conductive layer 2000 may include a first initialization voltage line 2100, a second gate pattern 2200, a second gate voltage line 2300, and a third gate voltage line 2400. In an embodiment, the second conductive layer 2000 may include a conductive material.

The first initialization voltage line 2100 may extend along the first direction DR1. The first initialization voltage line 2100 may overlap the first active layer ACT1 in a plan view. Specifically, the first initialization voltage line 2100 may overlap a portion of the first active layer ACT1 that extends in an opposite direction to the second direction DR2 from the sixth channel portion C6 and is bent in a plan view.

The second gate pattern 2200 may be spaced apart from the first initialization voltage line 2100 in the second direction DR2. The second gate pattern 2200 may overlap the first gate pattern 1200 in a plan view. For example, the first gate pattern 1200 and the second gate pattern 2200 may overlap each other in a plan view to define a storage capacitor CST. Specifically, the first gate pattern 1200 may define the first terminal of the storage capacitor CST, and the second gate pattern 2200 may define the second terminal of the storage capacitor CST.

The second gate pattern 2200 may overlap the first gate pattern 1200 in a plan view. The second gate pattern 2200 may overlap the bottom metal layer BML in a plan view. The second gate pattern 2200 may expose a portion of the first gate pattern 1200. In addition, the second gate pattern 2200 may expose a portion of the bottom metal layer BML.

In an embodiment, the second gate pattern 2200 may define a third recess RP3. For example, the second gate pattern 2200 may have a concave shape in a plan view. Specifically, the second gate pattern 2200 may have a curved shape that defines the second recess RP2, in a plan view. However, the shape of the second gate pattern 2200 in a plan view according to embodiments of the present disclosure may not be limited thereto, and the second gate pattern 2200 may have various shapes that expose the upper surface of the first gate pattern 1200, in a plan view.

The second gate pattern 2200 may overlap the first active layer ACT1 in a plan view. For example, the second gate pattern 2200 may overlap the first-first channel portion C1-1 in a plan view. In an embodiment, the second gate pattern 2200 may overlap a portion of the first active layer ACT1 that does not overlap the first gate pattern 1200 in a plan view. For example, the second gate pattern 2200 may overlap a portion of the first active layer ACT1 disposed between the first-first channel portion C1-1 and the first-second channel portion C1-2 in a plan view.

In an embodiment, the second gate pattern 2200 may not overlap the first-second channel portion C1-2 of the first active layer ACT1 in a plan view. For example, the third recess RP3 may expose a portion of the first gate pattern 1200 overlapping the first-second channel portion C1-2. The third recess RP3 may be spaced apart from each of the first recess RP1 and the second recess RP2 in a direction opposite to the second direction DR2 in a plan view. The third recess RP3 may be located closer to the sixth channel portion C6 than to the fifth channel portion C5 in a plan view. However, a location of the third recess RP3 of the second gate pattern 2200 according to the embodiments of the present disclosure may not be limited thereto.

In an embodiment, an area of the second gate pattern 2200 may be greater than an area of the first gate pattern 1200. In an embodiment, the area of the second gate pattern 2200 may be greater than an area of the bottom metal layer.

The second gate voltage line 2300 may extend along the first direction DR1. In addition, the second gate voltage line 2300 may be spaced apart from the first initialization voltage line 2100 and the second gate pattern 2200 in the second direction DR2. The second gate voltage line 2300 may overlap the first active layer ACT1 in a plan view. For example, the second gate voltage line 2300 may overlap a portion of the first active layer ACT1 adjacent to the second channel portion C2 in the opposite direction DR2 in a plan view.

The third gate voltage line 2400 may extend along the first direction DR1. In addition, the third gate voltage line 2400 may be spaced apart from the second gate voltage line 2300 in the second direction DR2. The third gate voltage line 2400 may overlap the first active layer ACT1 in a plan view. For example, the third gate voltage line 2400 may overlap a portion of the first active layer ACT1 adjacent to the seventh channel portion C7 in the second direction DR2 in a plan view.

The first interlayer-insulating layer ISL1 may be disposed on the second conductive layer 2000. In an embodiment, the first interlayer-insulating layer ISL1 may have a uniform thickness along the profile of the second conductive layer 2000. In another embodiment, the first interlayer-insulating layer ISL1 may have a substantially flat upper surface without creating a step around the second conductive layer 2000. In an embodiment, the first interlayer-insulating layer ISL1 may include an inorganic insulating material.

The second active layer ACT2 may be disposed on the first interlayer-insulating layer ISL1. The second active layer ACT2 may not overlap the first active layer ACT1 in a plan view. In an embodiment, the first active layer ACT1 and the second active layer ACT2 may include different materials. In an embodiment, the first active layer ACT1 may include a silicon semiconductor, and the second active layer ACT2 may include an oxide semiconductor. However, the materials included in each of the first active layer ACT1 and the second active layer ACT2 according to the embodiments of the present disclosure may not be limited thereto.

The second active layer ACT2 may include a third channel portion C3 and a fourth channel portion C4. The third channel portion C3 and the fourth channel portion C4 may be spaced apart from each other in a plan view. For example, the third channel portion C3 may be spaced apart from each other in a plan view in the second direction DR2 from the fourth channel portion C4. The third channel portion C3 of the second active layer ACT2 may overlap the second gate voltage line 2300 in a plan view. The fourth channel portion (C4) of the second active layer ACT2 may overlap the third gate voltage line 2400 in a plan view.

The third gate insulating layer GIL3 may be disposed on the second active layer ACT2. In an embodiment, the third gate insulating layer GIL3 may have a uniform thickness along the profile of the second active layer ACT2. In another embodiment, the third gate insulating layer GIL3 may have a substantially flat upper surface without creating a step around the second active layer ACT2. In an embodiment, the third gate insulating layer GIL3 may include an inorganic insulating material.

The third conductive layer 3000 may be disposed on the third gate insulating layer GIL3. The third conductive layer 3000 may include a fourth gate voltage line 3100 and a fifth gate voltage line 3200. In an embodiment, the third conductive layer 3000 may include a conductive material.

The fourth gate voltage line 3100 may extend along the first direction DR1. The fourth gate voltage line 3100 may overlap the second gate voltage line 2300 in a plan view. The fourth gate voltage line 3100 may overlap the second active layer ACT2 in a plan view. For example, the fourth gate voltage line 3100 may overlap the third channel portion C3 of the second active layer ACT2 in a plan view. Specifically, a portion of the fourth gate voltage line 3100 overlapping the third channel portion C3 in a plan view may correspond to the gate terminal of the third transistor T3.

In addition, when the third transistor T3 has a dual gate structure, a portion of the fourth gate voltage line 3100 overlapping the third channel portion C3 in a plan view may correspond to the upper gate terminal of the third transistor T3, and a portion of the second gate voltage line 2300 overlapping the third channel portion C3 in a plan view may correspond to the bottom gate terminal of the third transistor T3.

The fifth gate voltage line 3200 may extend along the first direction DR1. The fifth gate voltage line 3200 may be spaced apart from the fourth gate voltage line 3100 in the second direction DR2. The fifth gate voltage line 3200 may overlap the third gate voltage line 2400 in a plan view. The fifth gate voltage line 3200 may overlap the second active layer ACT2 in a plan view. For example, the fifth gate voltage line 3200 may overlap the fourth channel portion C4 of the second active layer ACT2 in a plan view. Specifically, a portion of the fifth gate voltage line 3200 overlapping the fourth channel portion C4 in a plan view may correspond to the gate terminal of the fourth transistor T4.

In addition, when the fourth transistor T4 has a dual gate structure, a portion of the fifth gate voltage line 3200 overlapping the fourth channel portion C4 in a plan view may correspond to the upper gate terminal of the fourth transistor T4, and a portion of the third gate voltage line 2400 overlapping the fourth channel portion C4 in a plan view may correspond to the bottom gate terminal of the fourth transistor T4.

The second interlayer-insulating layer ISL2 may be disposed on the third conductive layer 3000. In an embodiment, the second interlayer-insulating layer ISL2 may have a uniform thickness along the profile of the third conductive layer 3000. In another embodiment, the second interlayer-insulating layer ISL2 may have a substantially flat upper surface without creating a step around the third conductive layer 3000. In an embodiment, the second interlayer-insulating layer ISL2 may include an inorganic insulating material.

The fourth conductive layer 4000 may be disposed on the second interlayer-insulating layer ISL2. The fourth conductive layer 4000 may include a first connection electrode 4100, a second connection electrode 4200, a third connection electrode 4300, a fourth connection electrode 4400, a fifth connection electrode 4500, a sixth connection electrode 4600, and a second initialization voltage line 4700. In an embodiment, the fourth conductive layer 4000 may include a conductive material. At least one of the insulating layers (e.g., the first, second, and third gate insulating layers GIL1, GIL2, and GIL3, the first interlayer-insulating layer ISL1, and the second interlayer-insulating layer ISL2) disposed under the fourth conductive layer 4000 may have contact holes defined for contacting the fourth conductive layer 4000 among the bottom metal layer BML, the first active layer ACT1 and the second active layer ACT2 of the first, second, and third conductive layers 1000, 2000, and 3000.

The first connection electrode 4100 may overlap the first gate pattern 1200 and the second active layer ACT2 in a plan view. The first connection electrode 4100 may be electrically connected to the first gate pattern 1200 and the second active layer ACT2, respectively. For example, the first connection electrode 4100 may contact the first gate pattern 1200 and the second active layer ACT2 through the contact holes, respectively. Accordingly, the gate terminal of the first sub-transistor T1-1, the gate terminal of the second sub-transistor T1-2, the second terminal of the third transistor T3, and the first terminal of the fourth transistor T4 may be electrically connected to each other through the first connection electrode 4100.

The second connection electrode 4200 may be spaced apart from the first connection electrode 4100 in the first direction DR1. The second connection electrode 4200 may overlap the first active layer ACT1 and the second active layer ACT2 in a plan view, respectively. The second connection electrode 4200 may be electrically connected to the first active layer ACT1 and the second active layer ACT2, respectively. For example, the second connection electrode 4200 may contact each of the first active layer ACT1 and the second active layer ACT2 through the contact holes. Accordingly, the second terminal of the second sub-transistor T1-2, the first terminal of the third transistor T3, and the first terminal of the sixth transistor T6 may be electrically connected to each other through the second connection electrode 4200.

The third connection electrode 4300 may be spaced apart from the second connection electrode 4200 in the opposite direction of the second direction DR2. The third connection electrode 4300 may overlap the first active layer ACT1 in a plan view. The third connection electrode 4300 may be electrically connected to the first active layer ACT1. For example, the third connection electrode 4300 may contact the first active layer ACT1 through the contact hole. Accordingly, the third connection electrode 4300 may be connected to the second terminal of the sixth transistor T6.

The fourth connection electrode 4400 may be spaced apart from the third connection electrode 4300 in the opposite direction of the second direction DR2. The fourth connection electrode 4400 may overlap the second active layer ACT2 in a plan view. The fourth connection electrode 4400 may be electrically connected to the second active layer ACT2. For example, the fourth connection electrode 4400 may contact the second active layer ACT2 through a contact hole. Accordingly, the fourth connection electrode 4400 may be connected to the second terminal of the fourth transistor T4.

The fifth connection electrode 4500 may be spaced apart from the third connection electrode 4300 in the opposite direction of the first direction DR1. The fifth connection electrode 4500 may overlap the first active layer ACT1 and the second gate pattern 2200 in a plan view. The fifth connection electrode 4500 may be electrically connected to each of the first active layer ACT1 and the second gate pattern 2200. For example, the fifth connection electrode 4500 may contact each of the first active layer ACT1 and the second gate pattern 2200 through contact holes. Accordingly, the first terminal of the fifth transistor T5 and the second terminal of the storage capacitor CST may be electrically connected to each other through the fifth connection electrode 4500.

The sixth connection electrode 4600 may be spaced apart from the fifth connection electrode 4500 in a second direction DR2. The sixth connection electrode 4600 may overlap the first active layer ACT1 in a plan view. The sixth connection electrode 4600 may be electrically connected to the first active layer ACT1. For example, the sixth connection electrode 4600 may contact the first active layer ACT1 through a contact hole. Accordingly, the sixth connection electrode 4600 may be connected to the first terminal of the second transistor T2.

The second initialization voltage line 4700 may extend along the first direction DR1. The second initialization voltage line 4700 may be spaced apart from the sixth connection electrode 4600 in the opposite direction of the second direction DR2. The second initialization voltage line 4700 may overlap the first active layer ACT1 in a plan view. The second initialization voltage line 4700 may be electrically connected to the first active layer ACT1. For example, the second initialization voltage line 4700 may contact the first active layer ACT1 through the contact hole. Accordingly, the second initialization voltage line 4700 may be connected to the first terminal of the seventh transistor T7.

The first via-insulating layer VIA1 may be disposed on the fourth conductive layer 4000. The first via-insulating layer VIA1 may have a substantially flat upper surface. In an embodiment, the first via-insulating layer VIA1 may include an organic insulation material and/or an inorganic insulation material. For example, the organic insulation material may include a polyimide.

The fifth conductive layer 5000 may be disposed on the first via-insulating layer VIA1. The fifth conductive layer 5000 may include a data voltage line 5100, a power voltage line 5200, and a seventh connection electrode 5300. In an embodiment, the fifth conductive layer 5000 may include a conductive material. Contact holes for contacting the fifth conductive layer 5000 among the first, second, third, and fourth conductive layers 1000, 2000, 3000, and 4000), the first active layer ACT1, and the second active layer ACT2 may be defined in at least one of the insulating layers (e.g., the first, second, and third gate insulating layers GIL1, GIL2, and GIL3, the first interlayer-insulating layer ISL1, the second interlayer-insulating layer ISL2, and the first via-insulating layer VIA1) disposed under the fifth conductive layer 5000.

The data voltage line 5100 may extend along the second direction DR2. The data voltage line 5100 may overlap the sixth connection electrode 4600 in a plan view. The data voltage line 5100 may be electrically connected to the sixth connection electrode 4600. For example, the data voltage line 5100 may contact the sixth connection electrode 4600 through the contact hole. Accordingly, the data voltage line 5100 may be connected to the first terminal of the second transistor T2.

The power voltage line 5200 may be spaced apart from the data voltage line 5100 in the first direction DR1. The power voltage line 5200 may extend along the second direction DR2. The power voltage line 5200 may overlap the fifth connection electrode 4500 in a plan view. The power voltage line 5200 may be electrically connected to the fifth connection electrode 4500. For example, the power voltage line 5200 may contact the fifth connection electrode 4500 through the contact hole. Accordingly, the power voltage line 5200 may be connected to each of the first terminal of the fifth transistor T5 and the second terminal of the storage capacitor CST.

In the display device DD described with reference to FIGS. 5, 6, 7, 8, 9, 10, 11, 12, 13, 14, 15, 16, and 17, a contact hole electrically connecting the power voltage line 5200 and the bottom metal layer BML may not be illustrated, however, the present disclosure may not be limited thereto, and the power voltage line 5200 may be electrically connected to the bottom metal layer BML through the contact hole. When the power voltage line 5200 is electrically connected to the bottom metal layer BML through the contact hole, the bottom metal layer BML may overlap the first-first channel portion C1-1 to define the bottom gate terminal of the first sub-transistor T1-1. In addition, when the power voltage line 5200 is electrically connected to the bottom metal layer BML through the contact hole, the bottom metal layer BML may overlap the first-second channel portion C1-2 to define the bottom gate terminal of the second sub-transistor T1-2.

The seventh connection electrode 5300 may be spaced apart from the power voltage line 5200 in the first direction DR1. The seventh connection electrode 5300 may overlap the third connection electrode 4300 in a plan view. The seventh connection electrode 5300 may be electrically connected to the third connection electrode 4300. For example, the seventh connection electrode 5300 may contact the third connection electrode 4300 through the contact hole.

The second via-insulating layer VIA2 may be arranged on the fifth conductive layer 5000. The second via-insulating layer VIA2 may have a substantially flat upper surface. A contact hole may be defined in the second via-insulating layer VIA2 that penetrates the second via-insulating layer VIA2 in the third direction DR3 and exposes the upper surface of the seventh connection electrode 5300. In an embodiment, the second via-insulating layer VIA2 may include an organic insulating material and/or an inorganic insulating material.

The pixel electrode PXE may be disposed on the second via-insulating layer VIA2. The pixel electrode PXE may be electrically connected to the seventh connection electrode 5300 through the contact hole of the second via-insulating layer VIA2. Accordingly, the pixel electrode PXE may be electrically connected to the second terminal of the sixth transistor T6 through the third connection electrode 4300 and the seventh connection electrode 5300.

In an embodiment, the pixel electrode PXE may include a conductive material such as a metal, an alloy, a transparent conductive oxide, and the like. For example, the pixel electrode PXE may include silver (Ag), indium tin oxide (ITO), and the like. In an embodiment, the pixel electrode PXE may have a multilayer structure including an indium tin oxide layer, a silver layer, and an indium tin oxide layer that are stacked in a third direction DR3. However, the structure of the pixel electrode PXE according to embodiments of the present disclosure may not be limited thereto.

The pixel defining layer PDL may be disposed on the pixel electrode PXE. The pixel defining layer PDL may partially cover the pixel electrode PXE. In addition, an opening that exposes at least a portion of the pixel electrode PXE may be defined in the pixel defining layer PDL. For example, the opening of the pixel defining layer PDL may expose the center of the pixel electrode PXE, and the pixel defining layer PDL) may cover the edge of the pixel electrode PXE. The pixel defining layer PDL may include an organic insulating material, such as polyimide.

The light-emitting layer EML may be disposed on the pixel electrode PXE. The light-emitting layer EML may be disposed on the pixel electrode PXE exposed by the opening of the pixel defining layer PDL. The light-emitting layer EML may include an organic light-emitting material, a quantum dot, or the like.

The common electrode CE may be disposed on the light-emitting layer EML and the pixel defining layer PDL. The common electrode CE may include aluminum, platinum (Pt), silver, magnesium (Mg), gold (Au), chromium (Cr), tungsten (W), titanium, and the like. These may be used alone or in combination.

The pixel electrode PXE, the light-emitting layer EML, and the common electrode CE may define a light emitting element EE. In addition, the first active layer ACT1, the light-emitting control line 1100, the second connection electrode 4200, and the third connection electrode 4300 may define a sixth transistor T6. In addition, the second active layer ACT2, the fourth gate voltage line 3100, the first connection electrode 4100, and the second connection electrode 4200 may define a third transistor T3. In addition, although not shown in FIG. 17, the second active layer ACT2, the fifth gate voltage line 3200, the first connection electrode 4100, and the fourth connection electrode 4400 may define a fourth transistor T4. In addition, the first active layer ACT1, the first gate pattern 1200, the second connection electrode 4200, and the sixth connection electrode 4600 may define the first transistor T1.

In this specification, the second connection electrode 4200 and the sixth connection electrode 4600 may be referred to as a “first electrode” and a “second electrode”, respectively. In addition, the first connection electrode 4100 and the second connection electrode 4200 may be referred to as a “third electrode” and a “fourth electrode”, respectively. Alternatively, the first connection electrode 4100 and the fourth connection electrode 4400 may be referred to as the “third electrode” and the “fourth electrode”, respectively.

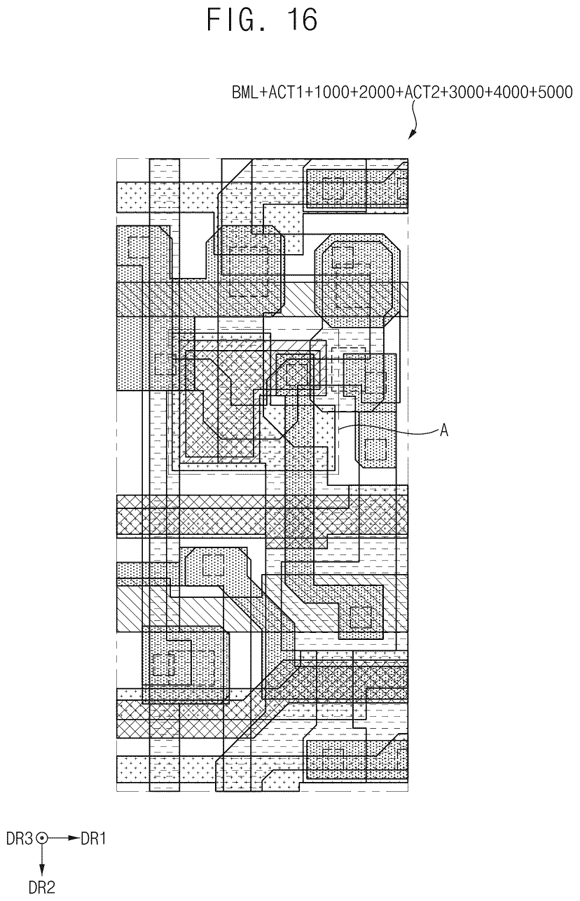

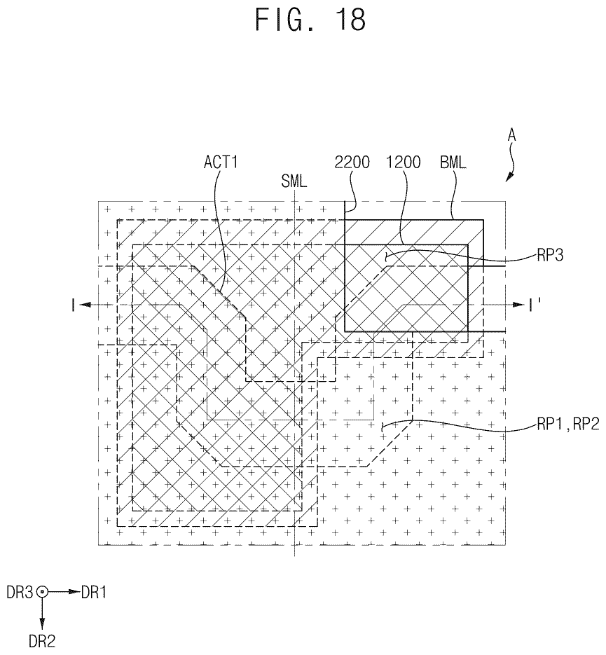

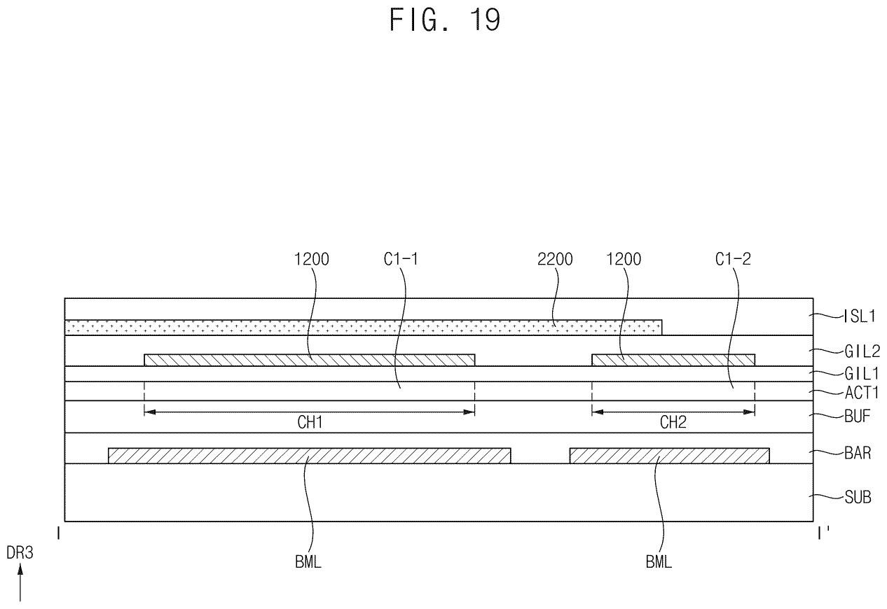

FIG. 18 is a layout view illustrating a first transistor according to an embodiment. FIG. 18 is an enlarged view of the area A in FIG. 16. FIG. 19 is a cross-sectional view illustrating a cross-section taken along line I-I′ of FIG. 18.

Referring to FIGS. 1, 2, 3, 4, 5, 6, 7, 8, 9, 10, 11, 12, 13, 14, 15, 16, 17, 18, and 19, the first-first channel portion C1-1 overlapping with the first gate pattern 1200 of the first gate pattern 1200 may be a channel of the first sub-transistor T1-1. In addition, the first-second channel portion C1-2 overlapping with the first gate pattern 1200 may be a channel of the second sub-transistor T1-2. A first channel length CH1 of the first-first channel portion C1-1 may be defined along a profile of the first active layer ACT1 in a plan view. In addition, a second channel length CH2 of the first-second channel portion C1—may be defined along a profile of the first active layer ACT1 in a plan view. Specifically, the first gate pattern 1200 may include a first portion overlapping with the first-first channel portion C1-1 and a second portion overlapping with the first-second channel portion C1-2. In a cross-sectional view, a length of the first-first channel portion C1-1 overlapping the first portion may be defined as the first channel length CH1, and a length of the first-second channel portion C1-2 overlapping the second portion may be defined as the second channel length CH2.

A curved shape of the first active layer ACT1 may be symmetrical with respect to an imaginary line SML that passes through a center of the portion of the first active layer ACT1 disposed between the first-first channel portion C1-1 and the first-second channel portion C1-2 and is parallel to the second direction DR2, in a plan view. However, a shape of the first active layer ACT1 in a plan view according to embodiments of the present disclosure may not be limited thereto, and a shape of the first active layer ACT1 may be asymmetrical with respect to an imaginary line SML, in a plan view.

In an embodiment, a shape of the first gate pattern 1200 may be asymmetrical with respect to the imaginary line SML in a plan view. Accordingly, the first-first channel portion C1-1 and the first-second channel portion C1-1 may be asymmetrical with respect to the imaginary line SML. Therefore, the first channel length CH1 and the second channel length CH2 may be different from each other.

In an embodiment, the first channel length CH1 may be longer than the second channel length CH2. In an embodiment, the first channel length CH1 may be about 10 micrometers (μm) to about 14 μm. Preferably, the first channel length CH1 may be about 12 μm. In an embodiment, the second channel length CH2 may be about 3 μm to about 5 μm. Preferably, the second channel length CH2 may be about 4 μm. In an embodiment, the sum of the first channel length CH1 and the second channel length CH2 may be about 20 μm or less. Preferably, the sum of the first channel length CH1 and the second channel length CH2 may be about 16 μm. However, a value or sum of each of the first channel length CH1 and the second channel length CH2 according to embodiments of the present disclosure may not be limited thereto.

In an embodiment, a shape of the bottom metal layer BML may be asymmetrical with respect to the imaginary line SML in a plan view. In an embodiment, a shape of the second gate pattern 2200 may be asymmetrical with respect to the imaginary line SML, in a plan view. The first recess RP1, the second recess RP2, and the third recess RP3 may be disposed in the first direction DR1 with respect to the imaginary line SML.

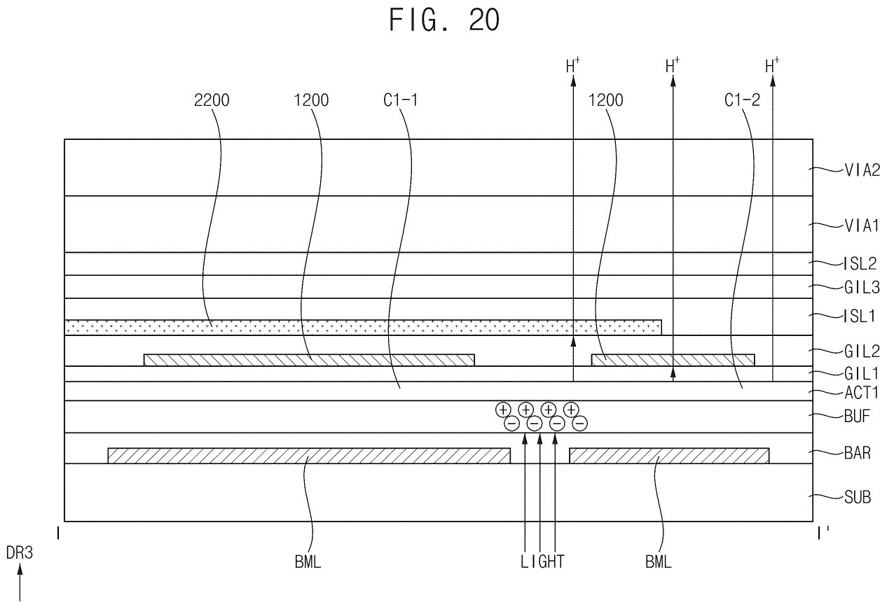

FIG. 20 is a view for explaining light inflow through a bottom metal layer of FIG. 19 and hydrogen emission from a first active layer.

Referring to FIGS. 1, 2, 3, 4, 5, 6, 7, 8, 9, 10, 11, 12, 13, 14, 15, 16, 17, 18, 19, and 20, as described above, the display device according to an embodiment of present disclosure may include a first active layer ACT1 including a first driving channel portion (e.g., the first-first channel portion C1-1) and a second driving channel portion (e.g., the first-second channel portion C1-2), the first gate pattern 1200 disposed on the first active layer ACT1, the second gate pattern 2200 disposed on the first gate pattern 1200, and the bottom metal layer BML disposed under the first active layer ACT1. Accordingly, a driving transistor (e.g., the first transistor T1) included in the display device DD has a dual transistor structure including two driving channels (CH1 and CH2), so that a total channel length is relatively reduced compared to a case that a driving transistor has one driving channel, and thus a hysteresis characteristic of the display device DD may be effectively improved.

Meanwhile, when a channel length of the driving transistor included in a conventional display device is reduced, a driving range and a swing width of the data voltage of the driving transistor are reduced, respectively, and when screens of the display device alternately display black and white screens, a phenomenon was generated in which afterimages or stains are momentarily visible on the screens.

Meanwhile, in the display device DD according to the embodiments of the present disclosure, the second recess RP2 defined by the first gate pattern 1200 may expose a portion of an upper surface of the first active layer ACT1 disposed between the first driving channel portion C1-1 and the second driving channel portion C1-2, the third recess RP3 defined by the second gate pattern 2200 may expose an upper surface of the first gate pattern 1200, and the first recess RP1 defined by the bottom metal layer BML may expose the rear surface of the first active layer ACT1. Accordingly, the movement path of hydrogen ions (H⁺) released from the first active layer ACT1 and diffusing to an upper portion of the second gate pattern 2200 may be reduced, so that a release of the hydrogen ions of the first active layer ACT1 may be facilitated. In addition, light flowing in from a lower portion of the bottom metal layer BML may flow toward the periphery of the first driving channel portion and the second driving channel portion. Accordingly, reduction in the driving range of the driving transistor and the swing width of the data voltage may be reduced, respectively. Accordingly, when displaying black and white screens alternately on the screens of the display device DD, a phenomenon in which an afterimage or stain is momentarily seen on the screens may be effectively prevented.

Here, the hysteresis may mean a difference between a threshold voltage of the first transistor T1 during a forward swing and a threshold voltage of the first transistor T1 during a reverse swing. A swing width of the data voltage may mean a difference between a driving range of the first transistor T1 during a forward swing and a driving range of the first transistor T1 during a reverse swing.

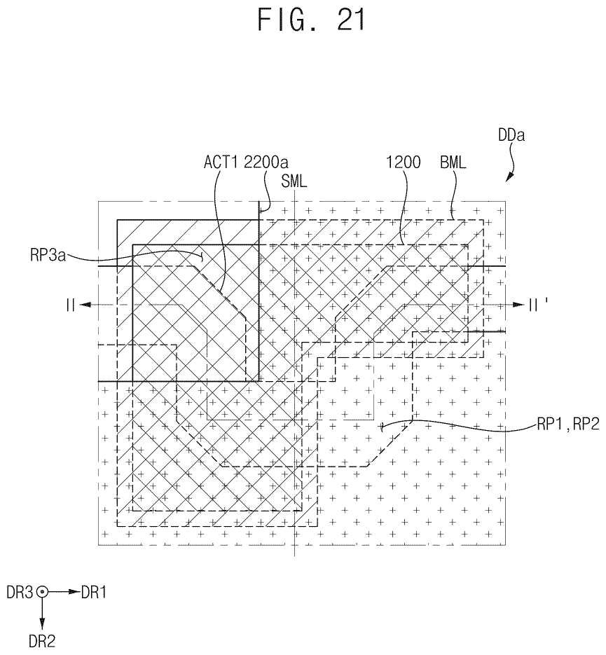

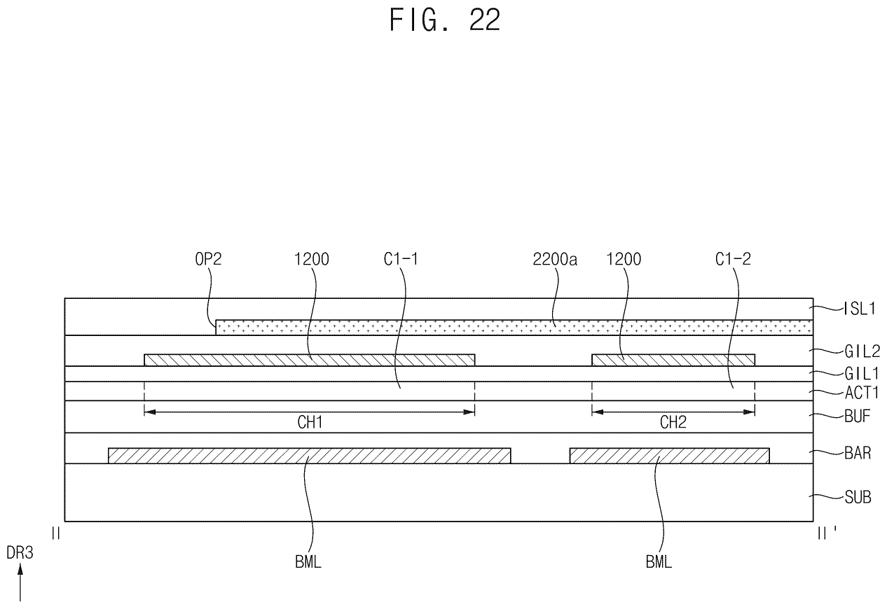

FIG. 21 is a layout view illustrating a first transistor according to another embodiment. FIG. 22 is a cross-sectional view illustrating a cross-section taken along line II-II′ of FIG. 21. For example, FIG. 21 is a view corresponding to FIG. 18.

A display device DDa described with reference to FIGS. 21 and 22 may be substantially the same or similar to the display device DD described with reference to FIGS. 18 and 19 except for a shape of a second gate pattern 2200a. Therefore, the content overlapping with the content described with reference to FIG. 18 and FIG. 19 will be omitted or simplified.

Referring to FIGS. 21 and 22, a display device DDa may include a second gate pattern 2200a defining a third recess RP3a. In an embodiment, the third recess RP3a may overlap with the first-first channel portion C1-1 in a plan view. Specifically, the third recess RP3a of the second gate pattern 2200a may expose a portion of an upper surface of the first gate pattern 1200 overlapping the first-first channel portion C1-1.

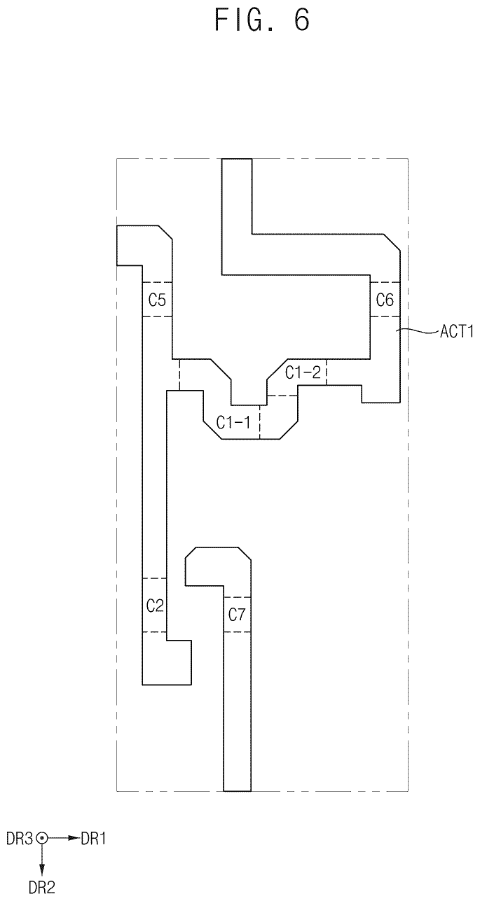

The third recess RP3a may be spaced apart from the first recess RP1 in a diagonal direction opposite to the first direction DR1 and the second direction DR2. In addition, the third recess RP3a may be spaced apart from the second recess RP2 in a diagonal direction opposite to the first direction DR1 and the second direction DR2. Accordingly, the second recess RP2 may be disposed closer to the fifth channel portion C5 of FIG. 6 than to the sixth channel portion C6 of FIG. 6.

The third recess RP3a may be disposed in the opposite direction of the first direction DR1 with respect to an imaginary line SML that passes through a center of the first active layer ACT1 and is parallel to the second direction DR2. That is, a shape of the second gate pattern 2200a of FIG. 21 may be symmetrical to a shape of the second gate pattern 2200 of FIG. 18 with respect to the imaginary line SML, in a plan view.

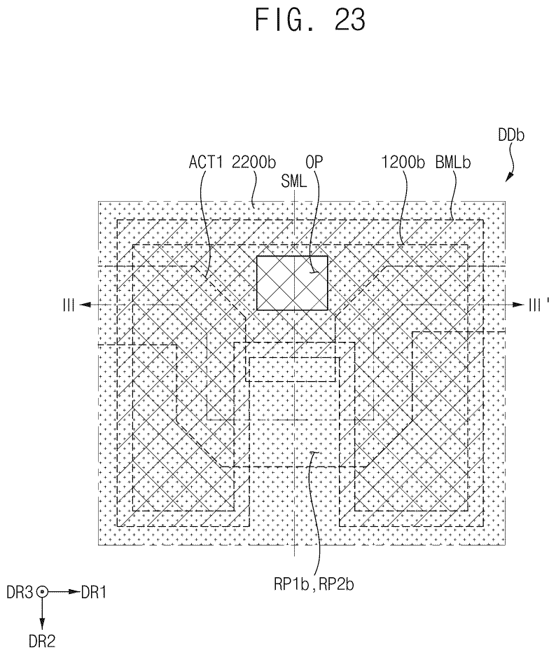

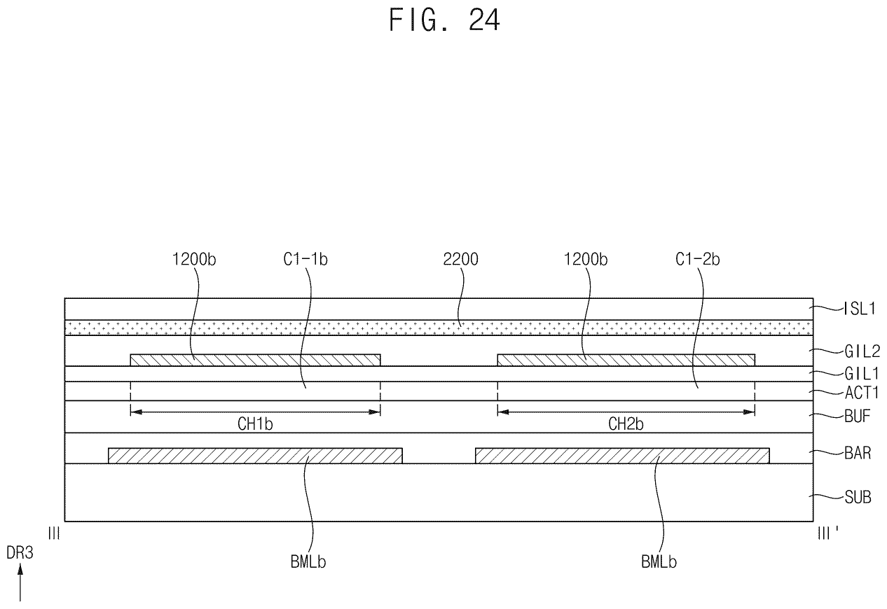

FIG. 23 is a layout view illustrating a first transistor according to still another embodiment. FIG. 24 is a cross-sectional view illustrating a cross-section taken along line III-III′ of FIG. 21. For example, FIG. 23 is a view corresponding to FIG. 18.

A display device DDb described with reference to FIGS. 23 and 24 may be substantially the same or similar to the display device DD described with reference to FIGS. 18 and 19 except for shapes of each of a bottom metal layer BMLb, a first gate pattern 1200b, and a second gate pattern 2200b. Accordingly, the overlapping content described with reference to FIGS. 18 and 19 will be omitted or simplified.

Referring to FIG. 23 and FIG. 24, A display device DDb may include a bottom metal layer BMLb defining a first recess RP1b, a first gate pattern 1200b defining a second recess RP2b, and a second gate pattern 2200b defining an opening OP. The first recess RP1b of the bottom metal layer BMLb may expose a rear surface of the first active layer ACT1. The second recess RP2b of the first gate pattern 1200b may expose an upper surface of the first active layer ACT1. The opening OP of the second gate pattern 2200b may expose an upper surface of the first gate pattern 1200b.

The first recess RP1b and the second recess RP2b may be defined as the bottom metal layer BMLb and the first gate pattern 1200b have concave shapes, respectively. In addition, the opening OP may be defined as a shape of a hole whose boundary is surrounded by the second gate pattern 2200b.

The first recess RP1b and the second recess RP2b may overlap each other in a plan view. The opening OP may be spaced apart from the first recess RP1b and the second recess RP2b in a plan view opposite to the second direction DR2.

A shape of each of the bottom metal layer BMLb, the first gate pattern 1200b, and the second gate pattern 2200b in a plan view may be parallel to the second direction DR2 and symmetrical with respect to an imaginary line SML passing through a center of the first active layer ACT1. In an embodiment, the imaginary line SML may pass through the center of each of the first recess RP1b, the second recess RP2b, and the opening OP. In an embodiment, each of the first recess RP1b, the second recess RP2b, and the opening OP may be symmetrical with respect to the imaginary line SML.

In an embodiment, a shape of the opening OP may have a rectangular shape, in a plan view. However, the shape of the opening OP in a plan view according to the embodiments of the present disclosure may not be limited thereto, and may have various shapes that may expose the upper surface of the first gate pattern 1200b, in a plan view. In addition, depending on a shape of the opening OP, the second gate pattern 2200b may have an asymmetrical shape with respect to the imaginary line SML, in a plan view.

In an embodiment, the bottom metal layer BMLb may have a shape (e.g., a ‘C’ shape) that is substantially the same as the shape of the first gate pattern 1200b in a plan view. Specifically, the bottom metal layer BMLb may have a ‘C’ shape that is symmetrical with respect to the imaginary line SML while completely surrounding an outer surface of the first gate pattern 1200b in a plan view. However, shapes of each of the bottom metal layer BMLb and the first gate pattern 1200b in a plan view according to the embodiments of the present disclosure may not be limited thereto.

The second gate pattern 2200b may overlap a portion of the first active layer ACT1 extending from a first-first channel portion C1-1b to a first-second channel portion C1-2b in a plan view. The opening OP may be spaced apart from the first recess RP1b in an opposite direction to the second direction DR2. In an embodiment, the opening OP may not overlap the first active layer ACT1 in a plan view. Specifically, the opening OP may expose an upper surface of a portion of the first gate pattern 1200b that does not overlap the first active layer ACT1. However, the location of the opening OP according to embodiments of the present disclosure may not be limited thereto, and the opening OP may overlap the first active layer ACT1 in a plan view.

In an embodiment, areas of the first-first channel portion C1-1b and the first-second channel portion C1-2b, which are portions of the first active layer ACT1 overlapping the first gate pattern 1200b, may be substantially equal to each other. Accordingly, a first channel length CH1b of the first-first channel portion C1-1b and a second channel length CH2b of the first-second channel portion C1-2b may be substantially equal to each other.

In an embodiment, the first channel length CH1b and the second channel length CH2b may each be about 6.5 μm to about 9.5 μm. Preferably, the first channel length CH1b and the second channel length CH2b may be about 8 μm. However, values of the first channel length CH1b and the second channel length CH2b according to embodiments of the present disclosure may not be limited thereto.

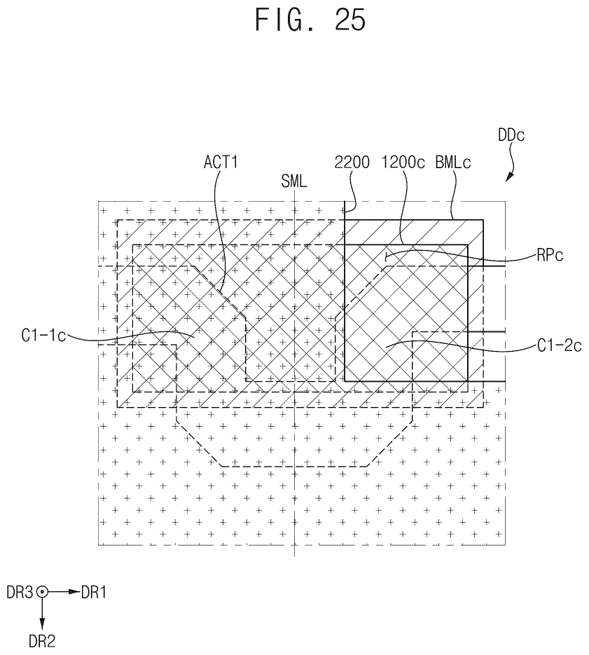

FIG. 25 is a layout view illustrating a first transistor according to yet another embodiment. For example, FIG. 25 is a view corresponding to FIG. 18.

A display device DDc described with reference to FIG. 25 may be substantially the same or similar to the display device DD described with reference to FIG. 18 except for shapes of each of a bottom metal layer BMLc and a first gate pattern 1200c. Accordingly, the content overlapping with the content described with reference to FIGS. 18 and 19 will be omitted or simplified.

Referring to FIG. 25, a display device DDc may include a bottom metal layer BMLc, a first gate pattern 1200c, and a second gate pattern 2200 defining a recess RPc. The bottom metal layer BMLc may expose at least a portion of a rear surface of a portion of the first active layer ACT1 disposed between a first-first channel portion C1-1c and a first-second channel portion C1-2c. The first gate pattern 1200c may expose a portion of an upper surface of the first active layer ACT1 disposed between the first-first channel portion C1-1c and the first-second channel portion C1-2c.

Each of the bottom metal layer BMLc and the first gate pattern 1200c may be symmetrical with respect to an imaginary line SML passing through a center of the first active layer ACT1 and parallel to the second direction DR2. In an embodiment, each of the bottom metal layer BMLc and the first gate pattern 1200c may have a rectangular shape in a plan view. However, a shape of the first gate pattern 1200c in a plan view according to embodiments of the present disclosure may not be limited thereto.

In an embodiment, a shape of the second gate pattern 2200 may be asymmetrical with respect to the imaginary line SML. The recess RPc of the second gate pattern 2200 may expose a portion of an upper surface of the first gate pattern 1200c overlapping the first-second channel portion C1-2c. However, the location of the recess RPc of the second gate pattern 2200 according to the embodiments of the present disclosure may not be limited thereto, and the recess RPc may expose a portion of an upper surface of the first gate pattern 1200c overlapping the first-first channel portion C1-1c, or may expose a portion of an upper surface of the first gate pattern 1200c that does not overlap the first active layer ACT1 in another embodiment. In addition, depending on the location of the recess RPc, the second gate pattern 2200 may have a shape that is symmetrical with respect to the imaginary line SML in a plan view.

The first gate pattern 1200c illustrated in FIG. 25 and the first gate pattern 1200b illustrated in FIG. 23 may both have a symmetrical shape with respect to the imaginary line SML in a plan view, but an area of a portion of the first gate pattern 1200c overlapping the first active layer ACT1 illustrated in FIG. 25 may be less than the area of a portion of the first gate pattern 1200b overlapping the first active layer ACT1 illustrated in FIG. 23. Accordingly, the sum of a first-first channel length CH1c and a first-second channel length CH2c of the display device DDc having the structure illustrated in FIG. 25 may be less than a sum of the first-first channel length CH1b and the first-second channel length CH2b of the display device DDb having the structure illustrated in FIG. 23.

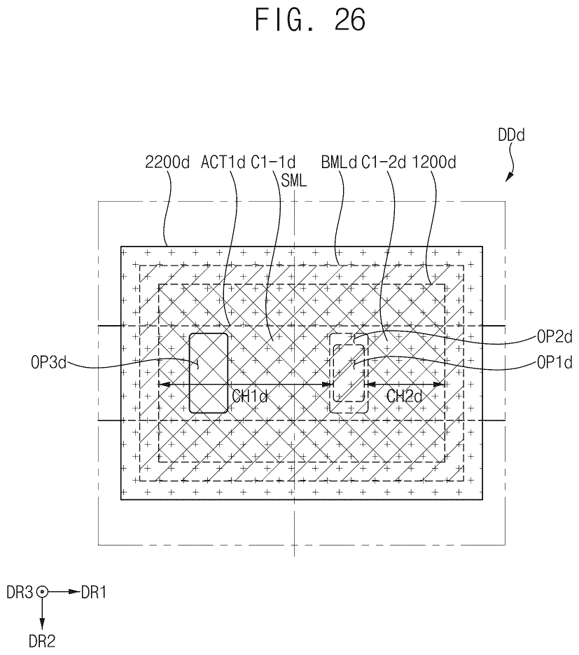

FIG. 26 is a layout view illustrating a first transistor according to still another embodiment. For example, FIG. 26 is a view corresponding to FIG. 18.

A display device DDd described with reference to FIG. 26 may be substantially the same or similar to the display device DD described with reference to FIG. 18 except for shapes of each of a bottom metal layer BMLd, a first active layer ACT1d, a first gate pattern 1200d, and a second gate pattern 2200d. Accordingly, the content overlapping with the content described with reference to FIG. 18 will be omitted or simplified.

Referring to FIG. 26, a display device DDd may include a bottom metal layer BMLd defining a first opening OP1d, a first active layer ACT1d, a first gate pattern 1200d defining a second opening OP2d, and a second gate pattern 2200d defining a third opening OP3d. The first opening OP1d may expose a rear surface of a portion of the first active layer ACT1d disposed between the first-first channel portion C1-1d and the first-second channel portion C1-2d. The second opening OP2d may expose an upper surface of a portion of the first active layer ACT1d disposed between the first-first channel portion C1-1d and the first-second channel portion C1-2d. The third opening OP3d may expose a portion of an upper surface of the first gate pattern 1200d. In an embodiment, the third opening OP3d may expose an upper surface of a portion of the first gate pattern 1200d overlapping the first-first channel portion C1-1d. However, a location of the third opening OP3d according to the embodiments of the present disclosure may not be limited thereto, and the third opening OP3d may expose a portion of an upper surface of the first gate pattern 1200d overlapping the first-second channel portion C1-2d.

The first, second, and third openings OP1d, OP2d, and OP3d may be defined as having a shape of holes whose boundaries are surrounded by the bottom metal layer BMLd, the first gate pattern 1200d, and the second gate pattern 2200d, respectively.

The first opening OP1d and the second opening OP2d may overlap each other in a plan view. The third opening OP3d may be spaced apart from each of the first opening OP1d and the second opening OP2d in the opposite direction of the first direction DR1. In an embodiment, the bottom metal layer BMLd, the first gate pattern 1200d, and the second gate pattern 2200d may have substantially the same shape in a plan view. For example, each of the bottom metal layer BMLd, the first gate pattern 1200d, and the second gate pattern 2200d may have a rectangular shape having one hole defined in a plan view. In an embodiment, the first active layer ACT1d may extend along the second direction DR2 and parallel to the second direction DR2. However, shapes of each of the first gate pattern 1200d, the second gate pattern 2200d, the bottom metal layer BMLd, and the first active layer ACT1d may not be limited thereto and may have various shapes in a plan view.

In an embodiment, a shape of each of the first gate pattern 1200d, the second gate pattern 2200d, and the bottom metal layer BMLd may be asymmetrical with respect to an imaginary line SML that passes through a center of the first active layer ACT1d and extends in a direction parallel to the second direction DR2, in a plan view. Since the first gate pattern 1200d has an asymmetrical shape with respect to the imaginary line SML, a first channel length CH1d and a second channel length CH2d may be different from each other, in a plan view. For example, the first channel length CH1d may be greater than the second channel length CH2d.

In an embodiment, the first opening OP1d and the second opening OP2d may be disposed in the first direction DR1 with respect to the imaginary line SML. In an embodiment, the third opening OP3d may be located in an opposite direction to the first direction DR1 with respect to the imaginary line SML.

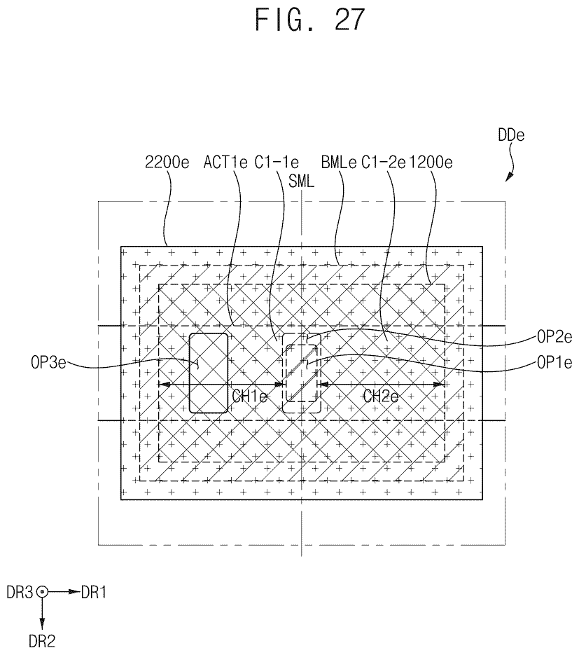

FIG. 27 is a layout view illustrating a first transistor according to yet another embodiment. For example, FIG. 27 is a view corresponding to FIG. 26.

A display device DDe described with reference to FIG. 27 may be substantially the same or similar to the display device DDd described with reference to FIG. 26, except for a shape of each of a bottom metal layer BMLe and a first gate pattern 1200e. Accordingly, the content overlapping with the content described with reference to FIG. 26 will be omitted or simplified.

Referring to FIG. 27, a display device DDe may include a bottom metal layer BMLe defining a first opening OP1e, a first active layer ACT1e, a first gate pattern 1200e defining a second opening OP2e, and a second gate pattern 2200e defining a third opening OP3e.

In an embodiment, a shape of each of the bottom metal layer BMLe and the first gate pattern 1200e may be symmetrical with respect to an imaginary line SML that passes through a center of the first active layer ACT1e and extends in a direction parallel to the second direction DR2, in a plan view. Since the first gate pattern 1200e has a shape that is symmetrical with respect to the imaginary line SML in a plan view, a first channel length CH1e and a second channel length CH2e may be substantially equal to each other. For example, the first channel length CH1e may be greater than the second channel length CH2e. The imaginary line SML may not intersect the third opening OP3e in a plan view.

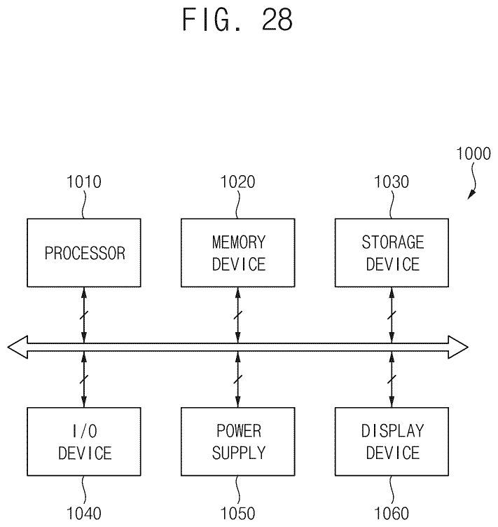

FIG. 28 is a block diagram illustrating an electronic device according to an embodiment.

Referring to FIG. 28, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

Although the devices according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a first active layer disposed on a substrate and including a first driving channel portion and a second driving channel portion which is spaced apart from the first driving channel portion;
a first gate pattern disposed on the first active layer, overlapping each of the first driving channel portion and the second driving channel portion in a plan view, and exposing a portion of the first active layer which is disposed between the first driving channel portion and the second driving channel portion;
a second gate pattern disposed on the first gate pattern, overlapping the first gate pattern in a plan view, and exposing a portion of the first gate pattern; and
a light-emitting element disposed on the second gate pattern.

2. The display device of claim 1, further comprising:
a bottom metal layer disposed between the substrate and the first active layer in a cross-sectional view, and overlapping each of the first driving channel portion and the second driving channel portion in the plan view.

3. The display device of claim 2, wherein the bottom metal layer exposes at least a portion of a rear surface of the portion of the first active layer which is disposed between the first driving channel portion and the second driving channel portion.

4. The display device of claim 2, wherein an area of the bottom metal layer is greater than an area of the first gate pattern.

5. The display device of claim 4, wherein the bottom metal layer overlaps an entirety of the first gate pattern in the plan view.

6. The display device of claim 2, wherein an area of the bottom metal layer is substantially equal to an area of the first gate pattern.

7. The display device of claim 2, wherein a shape of the first gate pattern is substantially the same as a shape of the bottom metal layer in the plan view.

8. The display device of claim 1, further comprising:
a first electrode and a second electrode, which are disposed on the second gate pattern and electrically connected to the first active layer,
wherein the first active layer, the first gate pattern, the first electrode, and the second electrode define a driving transistor together.

9. The display device of claim 8, wherein the driving transistor includes:
a first sub-transistor including the first driving channel portion; and
a second sub-transistor including the second driving channel portion.

10. The display device of claim 8, further comprising:
a second active layer disposed on the second gate pattern;
a third gate pattern disposed on the second active layer; and
a third electrode and a fourth electrode disposed on the third gate pattern and disposed in a same layer as the first electrode and the second electrode,
wherein the second active layer, the third gate pattern, the third electrode, and the fourth electrode define a compensation transistor or an initialization transistor.

11. The display device of claim 1, wherein the first active layer includes a silicon semiconductor,
and the second active layer includes an oxide semiconductor.

12. The display device of claim 1, wherein a length of the first driving channel portion is greater than a length of the second driving channel portion.

13. The display device of claim 1, wherein a length of the first driving channel portion is substantially equal to a length of the second driving channel portion.

14. The display device of claim 1, wherein the first driving channel portion and the second driving channel portion are symmetrical with respect to an imaginary line passing through a center of the first active layer, which is disposed between the first driving channel portion and the second driving channel portion in the plan view.

15. The display device of claim 1, wherein a portion of the first gate pattern exposed by the second gate pattern overlaps the first driving channel portion in the plan view.

16. The display device of claim 1, wherein a portion of the first gate pattern exposed by the second gate pattern overlaps the second driving channel portion in the plan view.

17. A display device comprising:
a data write transistor configured to transmit a data voltage to a first node in response to a write signal;
a driving transistor configured to generate a driving current corresponding to the data voltage and including:
a first sub-transistor which includes a first terminal connected to the first node, a second terminal opposite to the first terminal, and a gate terminal connected to a second node; and
a second sub-transistor which includes a first terminal connected to the second terminal of the first sub-transistor, a second terminal connected to a third node, and a gate terminal connected to the second node;
a storage capacitor configured to store the data voltage and including a first terminal connected to the second node and a second terminal configured to receive a driving voltage; and
a light-emitting element which emits light with a brightness corresponding to the driving current.

18. The display device of claim 17, wherein the first sub-transistor and the second sub-transistor are connected in series between the first node and the third node.

19. The display device of claim 17, further comprising:
a compensation transistor including a first terminal connected to the third node, a second terminal connected to the fourth node, and a gate terminal configured to receive a compensation signal; and
an initialization transistor including a first terminal connected to the fourth node, a second terminal configured to receive an initialization voltage, and a gate terminal configured to receive an initialization signal.

20. The display device of claim 19, wherein each of the compensation transistor and the initialization transistor is NMOS.

21. The display device of claim 19, wherein each of the compensation transistor and the initialization transistor is PMOS.

22. The display device of claim 17, further comprising:
a first active layer including a first driving channel portion which defines a channel of the first sub-transistor and a second driving channel portion which defines a channel of the second sub-transistor; and
a first gate pattern disposed on the first active layer and defining the gate terminal of the first sub-transistor and the gate terminal of the second sub-transistor.

23. The display device of claim 22, wherein the first gate pattern exposes a portion of the first active layer disposed between the first driving channel portion and the second driving channel portion.

24. The display device of claim 23, further comprising:
a second gate pattern disposed on the first gate pattern and defining the second terminal of the storage capacitor,
wherein the second gate pattern exposes a portion of the first gate pattern.

25. The display device of claim 24, further comprising:
a bottom metal layer disposed between a substrate and the first active layer in a cross-sectional view, and overlapping each of the first driving channel portion and the second driving channel portion in a plan view,
wherein the bottom metal layer exposes at least a rear surface of the portion of the first active layer disposed between the first driving channel portion and the second driving channel portion.

26. The display device of claim 25, wherein each of the first sub-transistor and the second sub-transistor further includes a bottom gate terminal, and
the bottom metal layer defines the bottom gate terminal of the first sub-transistor and the bottom gate terminal of the second sub-transistor.

27. An electronic device comprising:
a display device; and
a power supply configured to provide power to the display device,
wherein the display device comprises:
a first active layer disposed on a substrate and including a first driving channel portion and a second driving channel portion which is spaced apart from the first driving channel portion;
a first gate pattern disposed on the first active layer, overlapping each of the first driving channel portion and the second driving channel portion in a plan view, and exposing a portion of the first active layer which is disposed between the first driving channel portion and the second driving channel portion;
a second gate pattern disposed on the first gate pattern, overlapping the first gate pattern in a plan view, and exposing a portion of the first gate pattern; and
a light-emitting element disposed on the second gate pattern.
